(19) United States
(12) Patent Application Publication
(10) Pub. No.: US 2013/0235545 A1
(43) Pub. Date: Sep. 12, 2013

(54) MULTILAYER WIRING BOARD

(71) Applicants: Tadahiro Ohmi, Sendai-shi (JP); Tetsuya Goto, Sendai-shi (JP); Masakazu Hashimoto, Tokyo (JP)

(72) Inventors: Tadahiro Ohmi, Sendai-shi (JP); Tetsuya Goto, Sendai-shi (JP); Masakazu Hashimoto, Tokyo (JP)

(73) Assignees: ZEON CORPORATION, Tokyo (JP); NATIONAL UNIVERSITY CORPORATION TOHOKU UNIVERSITY, Sendai-shi, Miyagi (JP)

(21) Appl. No.: 13/884,844

(22) PCT Filed: Nov. 10, 2011
(86) PCT No.: PCT/JP2011/075992

§ 371 Date: May 10, 2013

(30) Foreign Application Priority Data
Nov. 12, 2010 (JP) 2010-253705

(51) Int. Cl. H05K 1/02; H05K 1/18

(52) U.S. Cl. CPC H05K 1/0237; H05K 1/181
USPC 361/783; 174/251; 361/760

(57) ABSTRACT

In a multilayer wiring board 100 having a high-density wiring region and a high-frequency propagation region mounted in the same board, it is possible to propagate a signal frequency of 40 GHz or more in the high-frequency propagation region by using a resin material with a dissipation factor (tan δ) of less than 0.01 as a material of an insulating layer used at least in the high-frequency propagation region. The insulating layer is formed of a polymerizable composition which contains a cycloolefin monomer, a polymerization catalyst, a cross-linking agent, a bifunctional compound having two vinylidene groups, and a trifunctional compound having three vinylidene groups and in which the content ratio of the bifunctional compound and the trifunctional compound is 0.5 to 1.5 in terms of a weight ratio value (bifunctional compound/trifunctional compound).

### TECHNICAL FIELD

This invention relates to a multilayer wiring board including a board for mounting thereon semiconductor elements such as LSIs or ICs and, in particular, relates to a semiconductor element mounting board and a multilayer wiring board in general that can reduce electrical signal loss in high-frequency application.

### BACKGROUND ART

A multilayer wiring board is widely used such that it is mounted with semiconductor elements and is, along with the semiconductor elements, accommodated in the same package to form a semiconductor device or such that it is mounted with a plurality of electronic components (semiconductor devices and other active components, passive components such as capacitors and resistance elements, etc.) to form an electronic device such as an information device, a communication device, or a display device (see, e.g. Patent Document 1). With higher propagation speed and miniaturization of these semiconductor, information, and other devices in recent years, an increase in signal frequency and signal line density has been advanced so that it is required to simultaneously achieve propagation of a high-frequency signal and high-density wiring.

However, since the propagation loss increases due to the increase in signal frequency and signal line density, it is difficult to ensure the reliability of a propagation signal and thus the problem of achieving the increase in signal line density and the propagation of a high-frequency signal in the same board has not been solved.

On the other hand, Patent Document 2 proposes a multilayer wiring board that achieves a reduction in propagation loss of a high-frequency signal propagation section and an increase in density of a low-frequency signal propagation section in the same board. Specifically, the multilayer wiring board proposed in Patent Document 2 comprises a first wiring region where a plurality of first wiring layers are laminated through a first insulating layer, and a second wiring region including a second insulating layer with a thickness which is twice or more a thickness of the first insulating layer and including a second wiring layer provided on the second insulating layer and having a width which is twice or more a width of the first wiring layer. In this manner, when the first wiring region where the wiring patterns and the insulating layer are alternately laminated and the second wiring region where the thickness of the insulating layer is twice or more and the line width is twice or more compared to the first wiring region are integrally formed in the same board, the first wiring region can be used mainly as a low-frequency signal propagation section while the second wiring region can be used mainly as a high-frequency signal propagation section.

In the multilayer wiring board having such a structure, it is possible, for example, to propagate mainly a signal having a frequency of 1 GHz or less in the first wiring region and to propagate mainly a high-frequency signal exceeding 1 GHz at a high speed for a long length of preferably 1 cm or more in the second wiring region.

Consequently, in the multilayer wiring board proposed in Patent Document 2, it is possible, while maintaining high mounting density by the first wiring region, to suppress propagation signal degradation by the second wiring region when a high-frequency signal propagates for a long length.

### PRIOR ART DOCUMENT

### Patent Document

Patent Document 1: JP-A-2007-288180
Patent Document 2: WO2009/147956

### SUMMARY OF THE INVENTION

### Problem to be Solved by the Invention

The proposal of Patent Document 2 shows very excellent development in solving the problem. However, it has been found that the dielectric loss of the insulating layer used therein is large so that the maximum frequency that can be propagated is restricted to 16.1 GHz. Consequently, it has been seen that it is not applicable to the case where higher performance is required.

It is therefore an object of this invention to provide a multilayer wiring board that achieves a reduction in propagation loss of a high-frequency signal propagation section and an increase in density of a low-frequency signal propagation section in the same board and that has a maximum frequency exceeding 16.1 GHz.

### Means for Solving the Problem

According to the present invention, there is provided a multilayer wiring board, in which a plurality of wiring layers are laminated through an insulating layer, comprising a first wiring region where wiring and insulating layers are alternately laminated and a second wiring region where, compared to the first wiring region, a thickness of an insulating layer is twice or more and a width of a wiring layer is twice or more, wherein the first wiring region and the second wiring region are integrally formed in the same board, characterized in that the insulating layer is made of a resin material (cross-linkable resin shaped product) formed by bulk-polymerizing and cross-linking a polymerizable composition which contains a cycloolefin monomer, a polymerization catalyst, a cross-linking agent, a bifunctional compound having two vinylidene groups, and a trifunctional compound having three vinylidene groups and in which a content ratio of the bifunctional compound and the trifunctional compound is 0.5 to 1.5 in terms of a weight ratio value (bifunctional compound/trifunctional compound). The resin material usually has a dissipation factor (tan δ) of less than 0.01.

In the multilayer wiring board having such a structure, the first wiring region is used mainly as a low-frequency signal propagation section while the second wiring region is used mainly as a high-frequency signal propagation section.

In this invention, the term “low frequency” which is used for a signal that propagates in the first wiring region means that the frequency of a signal that propagates in the first wiring region is lower than that of a signal that propagates in the second wiring region, while, the term “high frequency” which is used for a signal that propagates in the second wiring region means that the frequency of a signal that propagates in the second wiring region is higher than that of a signal that propagates in the first wiring region.

In this invention, a “wiring pattern” or a “wiring” represents a line formed of a material with a resistivity of less than 1 kΩ-cm as measured according to JISC3005 and is used as a concept including a circuit. The cross-sectional shape of a conductor is not limited to a rectangle and may be a circle, an ellipse, or another shape. The cross-sectional shape of an insulator is also not particularly limited.

In this invention, it is preferable that the second wiring region includes a portion comprising a third insulating layer with a thickness greater than the thickness of the second insulating layer and a third wiring layer provided on the third insulating layer and having a width greater than the width of the second wiring layer.

In this invention, by setting the thickness of a dielectric forming the insulating layer in the second wiring region and the line width to preferably 40 μm or more and 30 μm or more, respectively, it is possible to more effectively suppress signal degradation when mainly a high-frequency signal exceeding 8 GHz propagates for a long length of 1 cm or more.

In this invention, it is preferable that a conductor be formed to penetrate the insulating layer at a boundary portion between the first wiring region and the second wiring region and be grounded. By this, it is possible to suppress electrical coupling of signals in the first wiring region and the second wiring region to each other and thus to suppress radiation noise from the mutual signal lines.

The characteristic impedance of a signal line generally used at present is 50Ω. By designing the line width, the dielectric (insulating layer) thickness, and the line thickness in the first and second wiring regions so that the characteristic impedance becomes preferably 100Ω or more, it is possible to suppress a current that flows in the line and thus to reduce the propagation loss.

Using an insulating material with a dissipation factor (tan δ) of 0.002 or less as the insulating layers in the first wiring region and the second wiring region, it is possible to suppress propagation signal degradation. In particular, it is preferable to use an insulating material with a relative permittivity of 3.7 or less and a dissipation factor of 0.0015 or less as the insulating layer at least in the second wiring region of the first and second wiring regions.

### Effect of the Invention

According to this invention, while maintaining high mounting density by a first wiring region, it is possible to suppress propagation signal degradation by a second wiring region when a high-frequency signal propagates for a long length. Therefore, it is possible to achieve an increase in signal line density and an increase in propagation signal frequency in the same multilayer wiring board and, further, it is possible to achieve a maximum frequency of 40 to 80 GHz or higher that can be propagated.

### BRIEF DESCRIPTION OF THE DRAWINGS

FIG. 1 is a cross-sectional view showing the structure of a multilayer wiring board according to a first comparative example 1.

FIG. 2 is a cross-sectional view showing the manufacturing flow of the multilayer wiring board shown in FIG. 1.

FIG. 3 is a cross-sectional view showing the structure of a multilayer wiring board according to a second comparative example 2.

FIG. 4 is a cross-sectional view showing the structure of a multilayer wiring board according to a third comparative example 3.

FIG. 5 is a diagram showing relationships between the propagation loss and the signal frequency in a transmission line according to the first comparative example 1 and in a transmission line with a microstrip line structure formed in a second wiring region of a multilayer wiring board as a comparative example.

FIG. 6 is a characteristic diagram which derives relationships between the line width, the dielectric thickness (insulating layer thickness), and the propagation loss in the case of a dielectric with a relative permittivity of 2.6 and a dissipation factor of 0.01 at 10 GHz.

FIG. 7 is a characteristic diagram which derives relationships between the dielectric thickness (insulating layer thickness) and the propagation loss in the case of a dielectric with a relative permittivity of 2.6 and a dissipation factor of 0.01 at 10 GHz.

FIG. 8 is a characteristic diagram showing relationships between the dielectric thickness (insulating layer thickness) and the propagation loss for comparison in the case of different relative permittivities and dissipation factors.

FIG. 9 is a characteristic diagram showing relationships between the dielectric thickness (insulating layer thickness) and the propagation loss obtained under the same conditions as in FIG. 8 except the condition of frequency.

FIG. 10 is a cross-sectional view showing the structure of a multilayer wiring board according to a fourth comparative example 4.

FIG. 11 is a diagram for explaining the manufacturing flow of the multilayer wiring board shown in FIG. 10.

FIG. 12 is a diagram showing an example of wiring dimensions of microstrip lines used in the fourth comparative example 4.

FIG. 13 is a diagram imitating a cross-sectional image, observed by an optical microscope, of a multilayer wiring board manufactured as the fourth comparative example 4.

FIG. 14 is a diagram showing the propagation characteristics of the microstrip lines manufactured in the fourth comparative example 4.

FIG. 15 is a diagram showing the propagation characteristics of the microstrip lines manufactured in the fourth comparative example 4 and the calculation results of high-frequency RLGC models.

FIG. 16 is a diagram showing the available propagation length characteristics of the microstrip lines manufactured in the fourth comparative example 4.

FIG. 17 is a diagram showing the consumption power characteristics of the microstrip lines manufactured in the fourth comparative example 4.

FIG. 18 is a diagram showing the propagation characteristics of the microstrip lines manufactured in the fourth comparative example 4 in terms of the frequency fp that enables propagation with a loss suppressed to −3 dB for a length of 10 cm, and the consumption power P_{board} per wiring while comparing with a conventional example.

FIG. 19 is a diagram for explaining the characteristics of an insulating layer for use in a multilayer wiring board according to this invention and herein is a graph showing relationships between the width of a wiring layer and the characteristic impedance when the thickness of the insulating layer is changed in the state where the thickness (10 μm) of the wiring layer is fixed.

FIG. 20 is a diagram for explaining the characteristics of an insulating layer for use in a multilayer wiring board according to this invention and herein is a graph showing relationships between the thickness of an insulating layer and the propagation loss (S21) when the width and thickness of a wiring layer are each changed in a fixed proportion to the thickness of a polymerizable composition forming the insulating layer.

FIG. 21 is a diagram for explaining the characteristics of an insulating layer for use in a multilayer wiring board according to this invention and herein is a graph showing relationships between the frequency and the propagation loss when the thickness of an insulating layer and the thickness and width of a wiring layer are fixed.

FIG. 22 is a diagram for explaining the characteristics of an insulating layer for use in a multilayer wiring board according to this invention and herein is a graph showing relationships between the frequency and the propagation loss when the thickness of an insulating layer and the width of a wiring layer are set greater than those in FIG. 3.

FIG. 23 is a diagram for explaining the characteristics of an insulating layer for use in a multilayer wiring board according to this invention and herein is a graph showing relationships between the frequency and the propagation loss when the thickness of an insulating layer and the width of a wiring layer are set still greater than those in FIG. 4.

FIG. 24 is a cross-sectional view showing the structure of a multilayer wiring board according to a first embodiment of this invention.

### MODE FOR CARRYING OUT THE INVENTION

### First Comparative Example 1

Hereinbelow, comparative examples will be described with reference to the drawings before describing an embodiment of this invention.

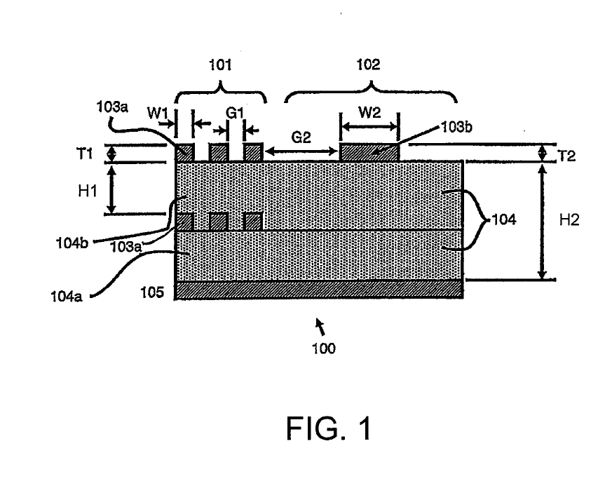

As shown in FIG. 1, a multilayer wiring board 100 of a first comparative example 1 has a first wiring region (multilayer wiring region) 101 and a second wiring region (multilayer wiring region) 102. The first wiring region (multilayer wiring region) 101 is formed such that plate-like or film-like insulating layers 104a and 104b and wirings 103a are alternately laminated. The second wiring region (multilayer wiring region) 102 is formed such that a wiring 103b is provided on an insulating layer 104 having an insulating layer thickness H2 which is twice or more an insulating layer thickness H1 per layer in the first wiring region 101. The wiring 103b has a line width W2 which is twice or more a line width W1 of the wiring 103a in the first wiring region 101. 105 denotes a conductive film.

The multilayer wiring board 100 of the first comparative example 1 is used, for example, as a semiconductor element package board. In the multilayer wiring board 100, the second wiring region 102 is used mainly in an application where the frequency of a signal transmitted from a terminal of a semiconductor element exceeds 1 GHz and the propagation length thereof exceeds 1 cm, while the first wiring region 101 is used in other than that application.

The insulating layer thickness H2 in the second wiring region 102 is not particularly limited, but, by setting it to preferably 40 μm or more, it is possible to largely reduce the propagation loss of a high-frequency signal exceeding 1 GHz. The line width W2 of the wiring 103b is not particularly limited, but, by setting it to preferably 30 μm or more, it is possible to largely reduce the propagation loss of a high-frequency signal exceeding 1 GHz.

The characteristic impedance of the first wiring region 101 is not particularly limited. On the other hand, by designing the line width, the dielectric (insulating layer) thickness, and the line thickness in the second wiring region 102 so that the characteristic impedance thereof becomes preferably 100Ω or more, it is possible to suppress a current that flows in the wiring and thus to reduce the propagation loss particularly at high frequencies.

A distance G1 between the wirings in the first wiring region 101 is not particularly limited. A distance G2 between the wirings in the boundary between the first wiring region 101 and the second wiring region 102 is not particularly limited, but, by setting it equal to or greater than the insulating layer thickness H2 in the second wiring region 102, it is possible to suppress coupling between the wirings and thus to suppress crosstalk noise. A thickness T1 of the wiring layer in the first wiring region 101 is not particularly limited. A thickness T2 of the wiring layer in the second wiring region 102 is not particularly limited, but, since a penetration depth d of an electromagnetic wave into the wiring is given by the following formula 1 where f is a propagation signal frequency, σ is a conductivity of the wiring 103b, and μ is a magnetic permeability of the wiring 103b, the thickness T2 is preferably equal to or greater than the value d.

$$d = \frac{1}{\sqrt{π f μ σ}} \qquad [ Formula 1 ]$$

A method of integrally forming the first wiring region 101 and the second wiring region 102 in the same board is carried out, for example, in the following manner.

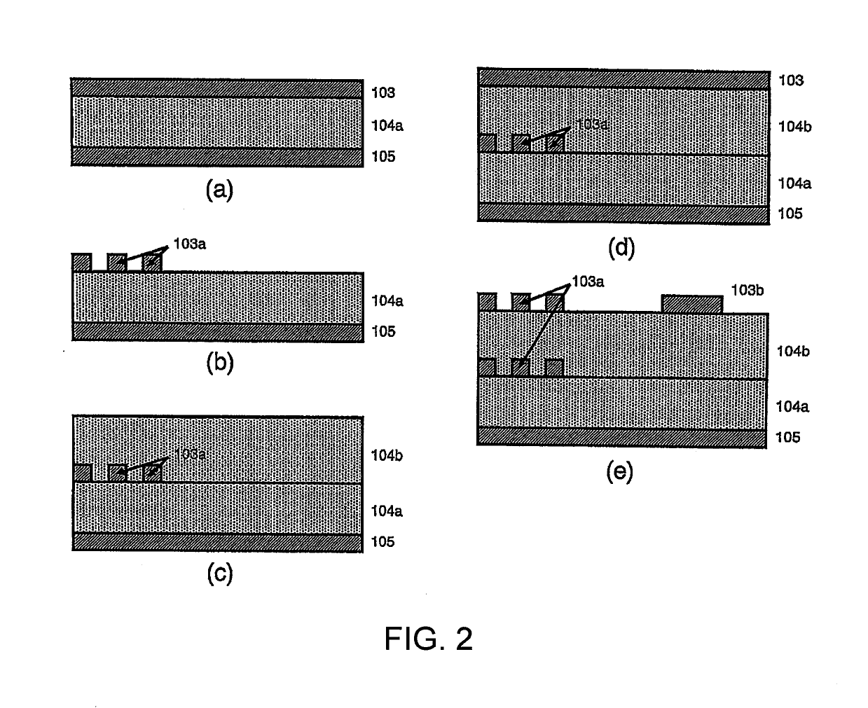

As shown at (a) in FIG. 2, first, a lower insulating layer 104a of an insulating layer 104 (FIG. 1) is formed into a sheet. A conductive film 105 of copper or the like is formed on a lower surface of the lower insulating layer 104a and a wiring layer 103 of copper or the like is formed on an upper surface of the lower insulating layer 104a. The conductive film 105 and the wiring layer 103 can each be, for example, a Cu film formed by a plating method, a sputtering method, or an organic metal CVD method, a film of a metal such as Cu formed by a bonding method, or the like.

Then, as shown at (b) in FIG. 2, the wiring layer 103 is patterned by a photolithography method or the like, thereby forming wirings 103a having predetermined patterns. The wirings 103a form the wiring patterns in the first wiring region 101 while the wiring layer in the second wiring region 102 is removed by an etching method or the like. Subsequently, as shown at (c) in FIG. 2, an upper insulating layer 104b is formed on the lower insulating layer 104a formed with the wirings 103a. The upper insulating layer 104b is formed into a sheet, for example, in the same manner as the lower insulating layer 104a and is bonded to the lower insulating layer 104a, for example, by a pressing method.

Thereafter, as shown at (d) in FIG. 2, a wiring layer 103 is formed on the upper insulating layer 104b. Subsequently, as shown at (e) in FIG. 2, the wiring layer 103 on the upper insulating layer 104b is patterned by a photolithography method or the like, thereby forming wirings 103a on the upper insulating layer 104b in the first wiring region 101 and forming a wiring 103b on the upper insulating layer 104b in the second wiring region 102.

The upper insulating layer 104b may alternatively be formed, for example, by a spin-coating method, a coating method, or the like.

### Second Comparative Example 2

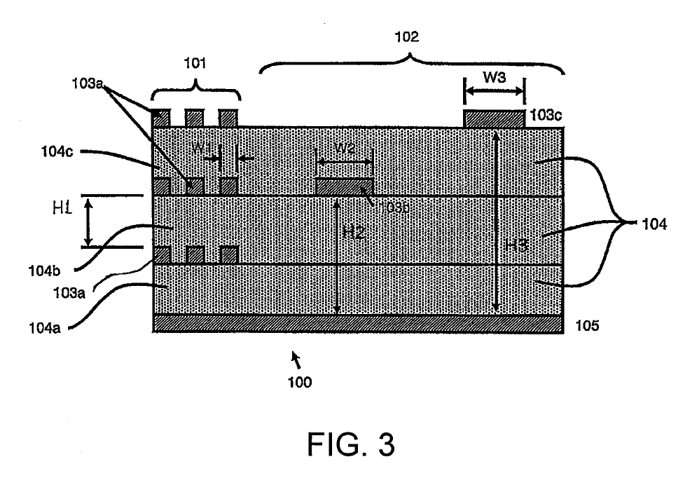

As shown in FIG. 3, in a second comparative example 2, an insulating layer 104c is formed on the uppermost-layer wirings 103a and 103b described in FIG. 1, wherein, on the insulating layer 104c, wirings 103a are formed in a first wiring region 101 and a wiring 103c is formed in a second wiring region 102 at its second portion other than its first portion where the wiring 103b is formed. At the second portion of the second wiring region 102, the insulating layer below the uppermost-layer wiring 103c is formed with no wiring layer and has an insulating layer thickness H3 which is three times or more the insulating layer thickness H1. The wiring 103c has a width W3 which is preferably greater than the width W2 of the wiring 103b at the first portion. The second comparative example has the same structure as the first comparative example except that the second wiring region (multilayer wiring region) 102 has the insulating layer 104 defined by a plurality of kinds of insulating layer thicknesses H2 and H3 which are twice or more the insulating layer thickness H1 per layer in the first wiring region (multilayer wiring region) 101 and has the wirings 103b and 103c defined by a plurality of kinds of line widths W2 and W3 which are twice or more the line width W1 of the wiring 103a.

Hereinbelow, the same symbols are assigned to those components common to the above-mentioned first comparative example, thereby partially omitting description thereof, and hereinbelow, only different points will be described in detail.

In the second comparative example, of the wirings with the plurality of kinds of insulating layer thicknesses in the second wiring region 102, the wiring with the structure having the greater insulating layer thickness below it, i.e. the wiring 103c on the insulating layer having the thickness H3, can more suppress the propagation loss of a high-frequency signal. Although, in FIG. 3, the wirings in the second wring region 102 are represented by the two kinds, i.e. 103b and 103c, the insulating layer thicknesses and the line widths in the wiring structure of the second wiring region 102 are not limited to the two kinds. Further, as long as the relationship to the wiring structure of the first wiring region 101 is satisfied, a combination between the insulating layer thickness and the line width in the wiring structure of the second wiring region 102 is not limited.

### Third Comparative Example 3

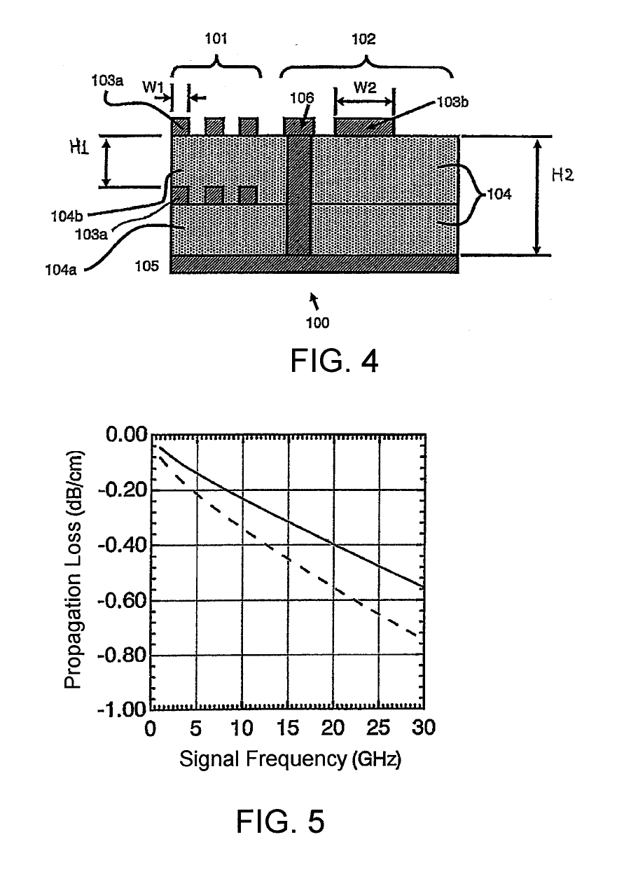

A third comparative example 3 will be described with reference to FIG. 4. Herein, it has the same structure as the first comparative example except that, in a boundary region between a first wiring region 101 and a second wiring region 102, a via (VIA) hole, i.e. a hole penetrating an insulating layer in a height direction, is provided and buried with a conductor so that a wiring 106 is formed to be connected to a ground electrode 105 through the conductor. By providing the via-hole conductor and the wiring 106 which are connected to the ground electrode 105, it is possible to suppress electrical coupling of a signal in a wiring in the first wiring region 101 and a signal in a wiring in the second wiring region 102 and thus to suppress noise to the signal propagating in the second wiring region 102.

In FIG. 4, the wiring 106 is connected to the conductive film 105 as the ground electrode. However, as long as the wiring 106 is connected to the ground electrode, its positional relationship to the ground electrode is not limited. Further, the cross-sectional structure of the wiring 106 or the cross-sectional structure of the via-hole conductor is not limited to a rectangular shape.

Instead of the structure of connecting the wiring 106 to the ground electrode (conductive film) 105 through the single via hole as shown in FIG. 4, the wiring 106 may be first connected to a land provided on a surface of a lower insulating layer 104a through a first via hole penetrating an upper insulating layer 104b and then the land may be connected to the ground electrode 105 through a second via hole penetrating the lower insulating layer 104a. This example will be described in detail later as an example 2. In this case, the first via hole and the second via hole may be arranged in an offset manner, i.e. not aligned in a straight line.

An insulating layer 104c may be formed, like in FIG. 3, on the structure of FIG. 4 and a ground wiring may be provided on the insulating layer 104c between a wiring 103b and a wiring 103c in the second wiring region 102 and connected to the ground electrode 105 through a via hole.

Hereinbelow, a further detailed structure of the first comparative example 1 will be described.

Referring to FIG. 1, as the first wiring region 101 and the second wiring region 102 each having the multilayer wiring structure described in the above-mentioned first comparative example 1, a microstrip line structure in which the thickness H1 of the insulating layer 104b was 40 μm, the line width W1 of the wiring 103a was 104 μm, and the line thickness T1 of the wiring 103a was 12 μm and a microstrip line structure in which the thickness H2 of the insulating layer 104 was 80 μm, the line width W2 of the wiring 103b was 215 μm, and the line thickness T2 of the wiring 103b was 12 μm were respectively formed in the same board by the above-mentioned methods.

In this comparative example 1, the distance G1 between the wirings in the first wiring region 101 was 100 μm while the distance G2 between the wiring 103a in the first wiring region 101 and the wiring 103b in the second wiring region 102 was 150 μm. As the insulating layer 104, use was made of a polycycloolefin-based insulating material with a relative permittivity of 2.5 at 1 GHz and a dissipation factor of 0.01 at 1 GHz which were obtained by a cavity resonance method. As the wirings 103a and 103b and the conductive film 105, metal copper with a resistivity of 1.8 μΩ-cm was deposited by a plating method.

Results of measuring the propagation loss at signal frequencies in the second wiring region 102 of the multilayer wiring board 100 by an S-parameter method are shown by a solid line in FIG. 5.

Assuming that the occupied cross-sectional area per wiring in the first wiring region 101 is 1, the occupied cross-sectional area of the wirings in the multilayer wiring board 100 in this example was 10.1.

(Prior Art 1)

A multilayer wiring board 100 was manufactured in the same manner as in the first comparative example 1 except that a second wiring region 102 had a microstrip line structure being the same as that of a first wiring region 101, wherein a thickness H2 of an insulating layer 104 was 40 μm and a line width W2 of a wiring 103b was 104 μm. Results of measuring the propagation loss at signal frequencies in this second wiring region 102 by the S-parameter method are shown by a dashed line in FIG. 5.

Assuming that the occupied cross-sectional area per wiring in the first wiring region 101 is 1, the occupied cross-sectional area of the wirings in the multilayer wiring board 100 in the prior art 1 was 7.0.

(Prior Art 2)

A multilayer wiring board 100 was manufactured in the same manner as in the first comparative example 1 except that a first wiring region 101 had a microstrip line structure being the same as that of a second wiring region 102, wherein the insulating layer thickness was 80 μm and the line width was 215 μm.

The propagation loss at signal frequencies in the second wiring region 102 of this multilayer wiring board 100 took values equal to those of the propagation loss at signal frequencies in the second wiring region 102 in the first comparative example 1.

Assuming that the occupied cross-sectional area per wiring in the first wiring region 101 is 1, the occupied cross-sectional area of the wirings in the multilayer wiring board 100 in the prior art 2 was 29.9.

As shown in FIG. 5, it was confirmed that the propagation loss of a high-frequency signal was made smaller in the comparative example 1 than in the prior art 1. Further, it was confirmed that it was possible to make the occupied cross-sectional area of the wirings smaller in the comparative example 1 than in the prior art 2.

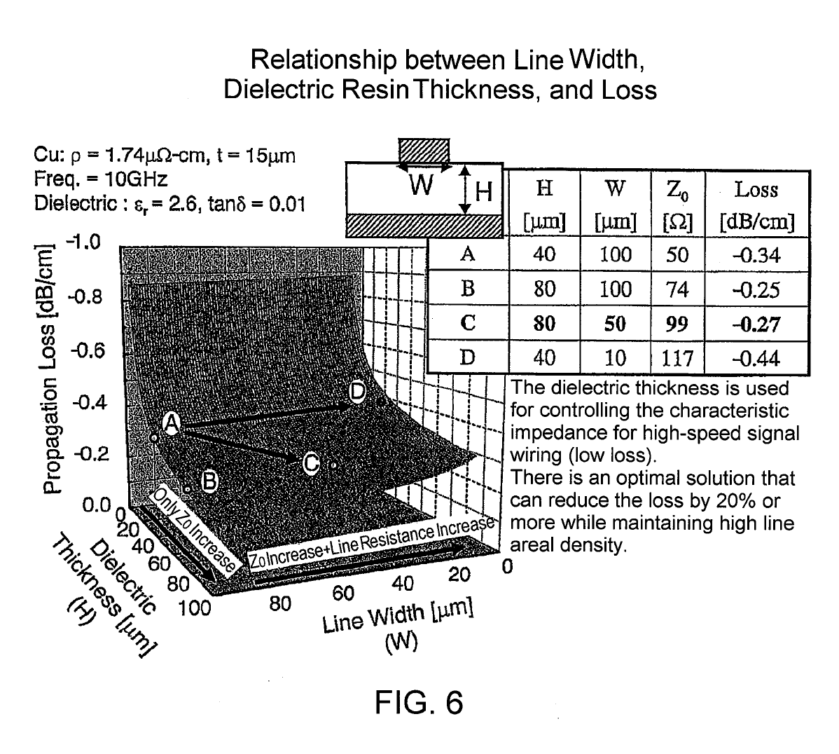

FIG. 6 is a characteristic diagram which derives relationships between the line width W, the dielectric thickness (insulating layer thickness) H, and the propagation loss in the case of a dielectric with a relative permittivity ∈ᵣ=2.6 and a dissipation factor tan δ=0.01 at 10 GHz.

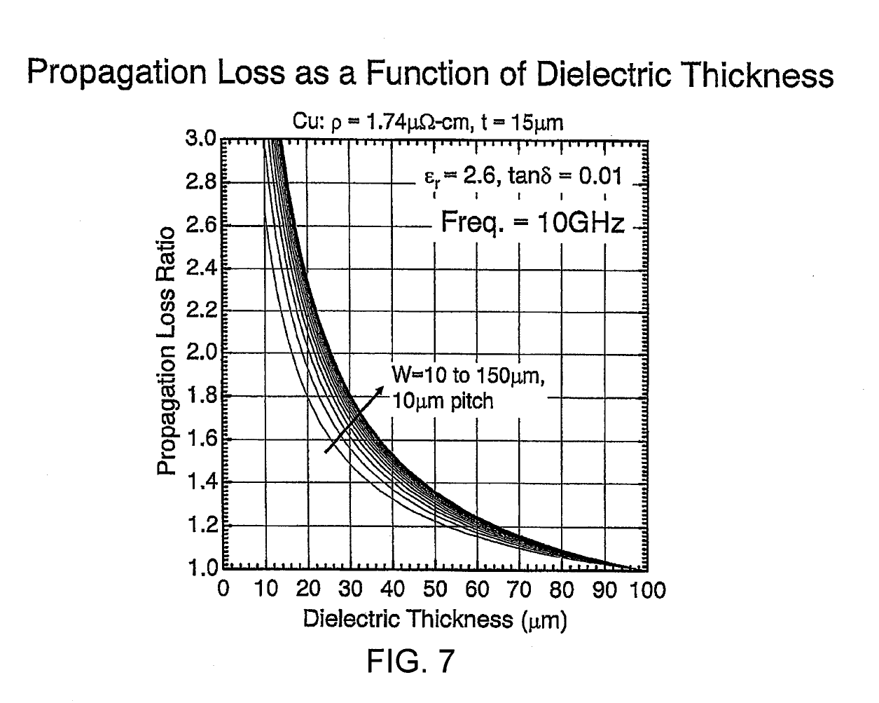

FIG. 7 is a characteristic diagram which derives relationships between the dielectric thickness (insulating layer thickness) and the propagation loss in the case of a dielectric with a relative permittivity ∈ᵣ=2.6 and a dissipation factor tan δ=0.01 at 10 GHz. As shown in FIG. 7, when the thickness of the insulating layer is set to 40 μm or more, the propagation loss is extremely reduced.

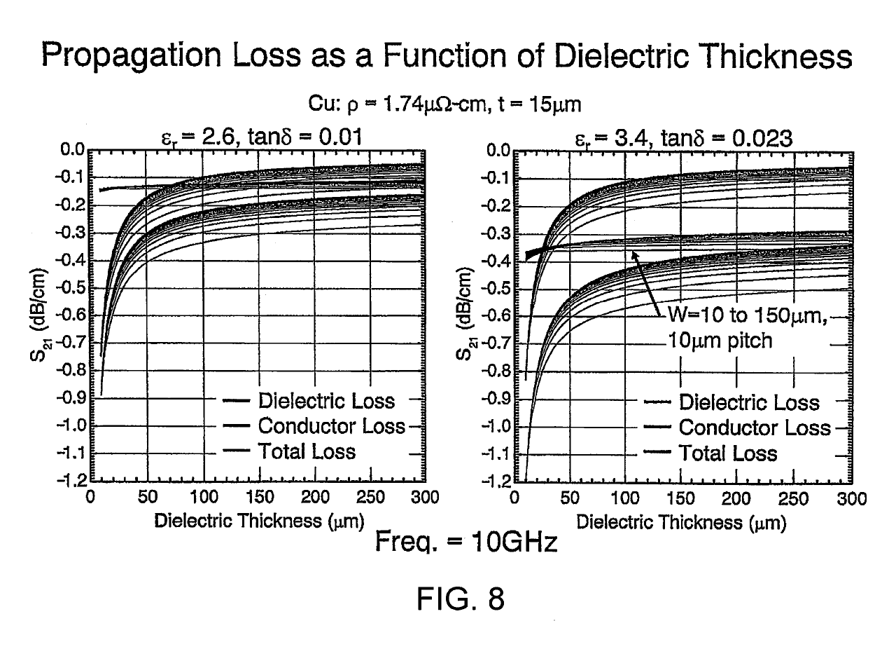

On the other hand, FIG. 8 is a diagram showing relationships between the dielectric thickness (insulating layer thickness) and the propagation loss in propagation of a 10 GHz signal for comparison between a dielectric with a relative permittivity ∈ᵣ=2.6 and a dissipation factor tan δ=0.01 at 10 GHz (on the left in the figure) and a dielectric with a relative permittivity ∈ᵣ=3.4 and a dissipation factor tan δ=0.023 at 10 GHz (on the right in the figure).

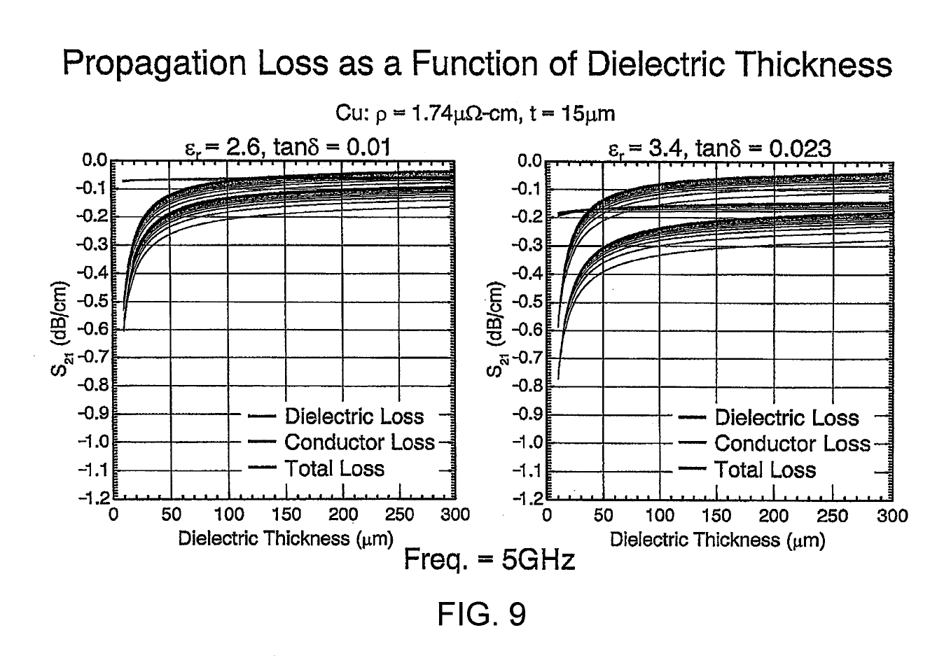

FIG. 9 shows relationships between the dielectric thickness (insulating layer thickness) and the propagation loss obtained under the same conditions as in FIG. 8 except a frequency of 5 GHz. It is seen that, as shown on the left in FIG. 9, in the case of the insulating layer with a relative permittivity ∈ᵣ=2.6 and a dissipation factor tan δ=0.01, the propagation loss can be extremely reduced compared to the right in FIG. 9.

From FIGS. 6 to 9, it can be confirmed that the propagation loss of a high-frequency signal can be reduced like in the first comparative example 1 and particularly that the propagation loss reduction effect by increasing the dielectric thickness, i.e. the insulating layer thickness, and reducing the relative permittivity and the dissipation factor of the insulating layer is significant. The propagation loss reduction effect is significant when the relative permittivity is 2.7 or less and the dissipation factor is 0.015 or less.

### Fourth Comparative Example 4

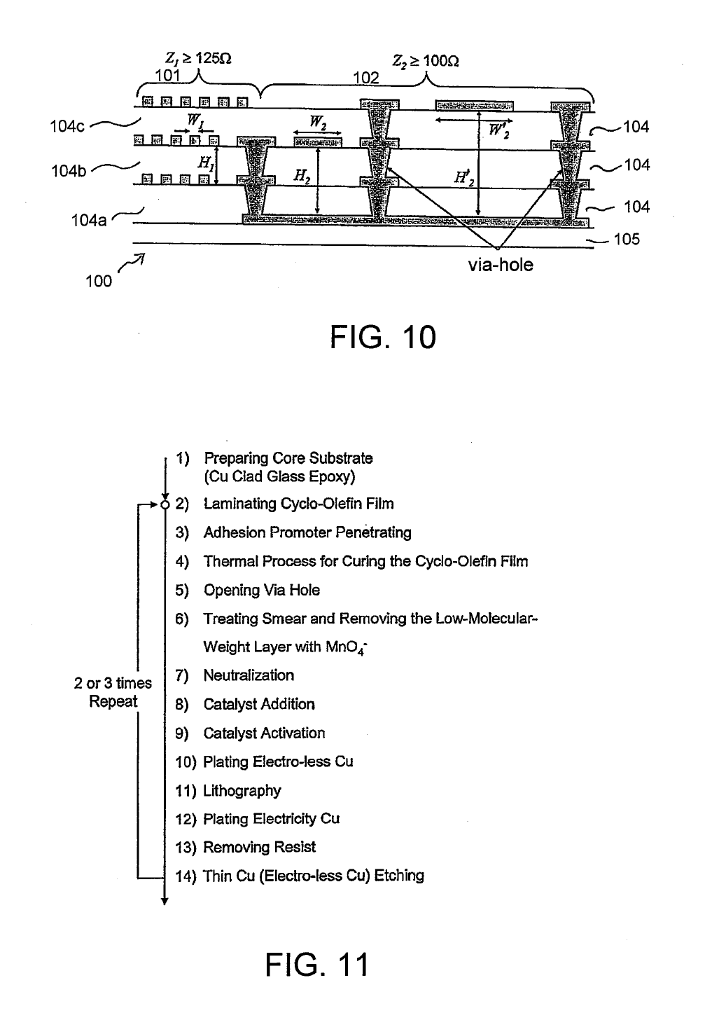

Referring to FIG. 10, a description will be given of a multilayer wiring board 100 as a fourth comparative example 4 which combines the second and third comparative examples 2 and 3 described with reference to FIGS. 3 and 4. This multilayer wiring board 100 can be called a high-impedance printed wiring board with a plurality of dielectric thicknesses mixed and its structure has, in the single printed wiring board 100, a region that can propagate an ultrahigh-frequency signal in a GHz band, particularly of 10 GHz or more, with a low consumption power, while suppressing a reduction in mounting density to minimum.

Features of this high-impedance printed wiring board with the plurality of dielectric thicknesses mixed are summarized as follows.

A) The single printed wiring board 100 has a high-density mounting region 101 for propagating a low-frequency DC power supply of 1 GHz or less and a high-frequency propagation region 102 that can achieve high-frequency propagation exceeding 1 GHz with a low loss.

B) In the high-density mounting region 101, the line width W is formed as small as possible, thereby improving the mounting density. In order to suppress the line loss, an extreme reduction in dielectric thickness H is not performed. In order also to keep a line characteristic impedance Z1 of the high-density mounting region 101 equal to or higher than 125Ω to thereby achieve a low consumption power, it is necessary to suppress the reduction in thickness of the dielectric film. For example, when a polycycloolefin resin film with a relative permittivity ∈ᵣ=2.60 is used and the dielectric film thickness and the line height are set to H1=40 μm and T=10 μm, respectively, the line width for providing the characteristic impedance Z1=125Ω is W1=9.4 μm. This wiring can be achieved by a smooth plating printed wiring technique.

C) The high-frequency propagation region 102 has a first portion and a second portion. In order to suppress the line metal loss, the dielectric film thickness is set to be twice (H2=2×H1) or more the dielectric film thickness of the high-density mounting region 101 at the first portion and to be three times (H2′=3×H1) or more at the second portion. These dielectric film thicknesses can be achieved by applying a build-up multilayer printed wiring board forming method. That is, a plated copper wiring on a lower-layer dielectric resin film in the high-frequency propagation region 102 is removed by etching during wiring patterning and then second-layer and third-layer resin films are built up thereon, thereby achieving the dielectric film thicknesses without newly introducing any special process. A characteristic impedance Z2 of the high-frequency propagation region 102 is set to 100Ω or more. This is for reducing the consumption power and suppressing an increase in line width following the increase in dielectric resin film thickness to thereby improve the mounting density. For example, when a dielectric resin film with a relative permittivity ∈ᵣ=2.60 is used and the dielectric film thickness and the line height are set to H2=80 μm and T=10 μm, respectively, the line width for providing the characteristic impedance Z2=50Ω is W2=209 μm. On the other hand, when the wiring is designed to provide the characteristic impedance Z2=100Ω, the line width becomes W2=52 μm so that the increase in line width can be suppressed while achieving ½ consumption power. A width W2′ of a wiring at the second portion is set greater than (preferably twice or more) the width W2 of the wiring at the first portion.

D) In the boundary between the high-frequency propagation region 102 and the high-density mounting region 101, a noise shield in the form of a via hole is provided for reducing electrical signal coupling between the wirings to suppress crosstalk noise that is superimposed on propagation signals. Also in the high-frequency propagation region 102, a noise shield in the form of a via hole is provided for reducing electrical signal coupling between the wirings at the first portion and the second portion.

Instead of the above-mentioned structure of connecting to the ground electrode (conductive film) 105 through the single via-hole conductor as shown in FIG. 4, this example employs the following structure. First, a land provided on a surface of a lower insulating layer 104a is connected to a ground electrode (conductive film) 105 through a via-hole conductor penetrating the lower insulating layer 104a, then the land provided on the surface of the lower insulating layer 104a is connected to a land provided on a surface of an upper insulating layer 104b through a via-hole conductor penetrating the upper insulating layer 104b, and further the land provided on the surface of the upper insulating layer 104b is connected to a land provided on a surface of an insulating layer 104c through a via-hole conductor.

In order to demonstrate the effect of the high-impedance printed wiring board with the plurality of dielectric thicknesses mixed according to the fourth comparative example 4, the following test was performed.

First, a high-impedance printed wiring board with a plurality of dielectric thicknesses mixed was manufactured according to the manufacturing flow of a build-up multilayer printed wiring board shown in FIG. 11. Using a polycycloolefin resin with a thickness H=40 μm as a dielectric resin film, a wiring region (characteristic impedance Z1=123Ω) with a dielectric thickness H1=40 μm, a line width W1=10 μm, and a line height T=10 μm and a wiring region (characteristic impedance Z2=101Ω) having a microstrip line with H2=80 μm, W2=50 μm, and T=10 μm were formed in the same board as a high-density mounting region 101 and a high-frequency propagation region 102, respectively, thereby demonstrating the high-impedance printed wiring board with the plurality of dielectric thicknesses mixed.

In the high-frequency propagation region 102, a first-layer copper plating wiring is removed during etching, thereby obtaining a thickness of 2×H=H2=80 μm including a second-layer dielectric resin film. This process flow can be achieved in a wiring forming process of a build-up multilayer printed wiring board using a technique of forming smooth plating on a polycycloolefin resin.

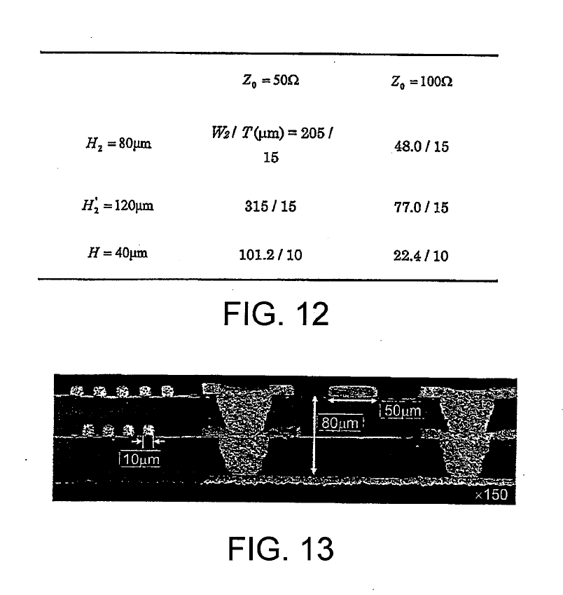

Then, in order to confirm the propagation characteristics of the high-frequency propagation region 102, microstrip line structures were formed by the same process as in FIG. 11, thereby judging the high-frequency propagation characteristics thereof. The dielectric film thickness was set to H2=80 μm or H2′=120 μm by laminating two or three polycycloolefin resin layers each having H=40 μm. There were manufactured two kinds of microstrip line structures, i.e. with line characteristic impedances Z0=50Ω and Z0=100Ω. The wiring dimensions of the manufactured microstrip line structures are shown in FIG. 12.

By comparing measured values of the propagation characteristics of the above-mentioned microstrip lines and the propagation characteristics of microstrip lines of H=40 μm, an influence of difference in dielectric film thickness given to the propagation characteristics was measured, thereby demonstrating the superiority of the high-impedance printed wiring board with the plurality of dielectric thicknesses mixed. Further, the propagation characteristics of the high-impedance printed wiring board with the plurality of dielectric thicknesses mixed were analyzed using high-frequency RLGC models and its superiority was confirmed.

FIG. 13 shows a diagram imitating a cross-sectional image, observed by an optical microscope, of a high-impedance printed wiring board with a plurality of dielectric thicknesses mixed (a multilayer wiring board manufactured as the fourth comparative example 4) which was manufactured using a smooth plated dielectric resin film with low permittivity and low dielectric loss. As a high-density mounting region on the left in the figure, wirings with a width W1=10 μm are formed per dielectric film layer of H1=40 μm, while, as a high-frequency propagation region on the left in the figure, a wiring with a line width W2=50 μm is precisely formed on a film thickness H2=80 μm corresponding to two dielectric film layers. This shows that the high-impedance printed wiring board with the plurality of dielectric thicknesses mixed can be formed by the build-up multilayer printed wiring board process.

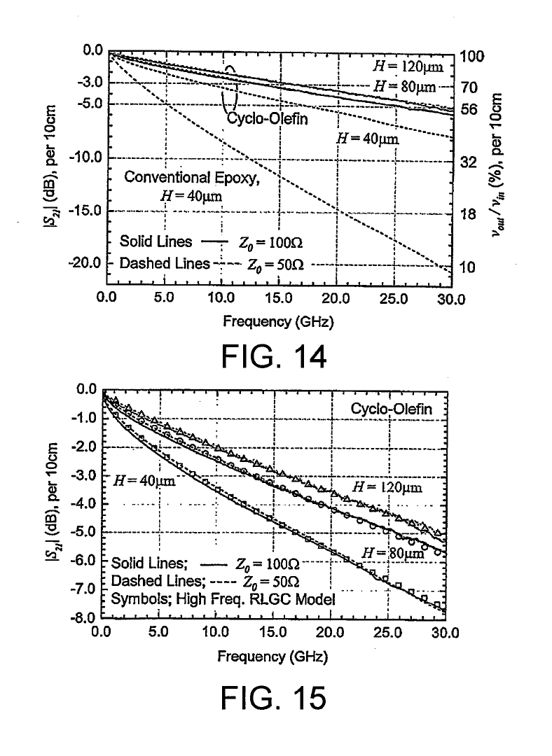

FIG. 14 shows the high-frequency propagation characteristics of the microstrip lines manufactured in the fourth comparative example 4. By reducing the propagation loss using a smooth plated dielectric resin film with low permittivity and low dielectric loss and further by setting the dielectric film thickness to H2=80 μm or H2′=120 μm, ultrahigh-frequency propagation exceeding 10 GHz is achieved with a propagation loss of −3 dB/10 cm. It was demonstrated that even if a wiring was miniaturized with a characteristic impedance being set to Z0=100Ω, the propagation loss was suppressed to be approximately equal to that of the microstrip line with Z0=50Ω. This is because since the line metal loss is approximately equal to “line resistance/(characteristic impedance)×2”, even if the line resistance increases by the miniaturization of the wiring, an increase in line loss can be prevented by increasing the characteristic impedance. In this manner, since the wiring can be miniaturized by increasing the characteristic impedance, while suppressing a reduction in in-plane mounting density also in the high-frequency signal propagation region, it is possible to propagate a propagation signal exceeding 10 GHz for 10 cm or more and further to suppress the consumption power per wiring to ½ or less compared to conventional.

FIG. 15 shows the same measurement results of the propagation characteristics as those in FIG. 14 and the calculation results of the propagation characteristics obtained by the high-frequency RLGC models. As the dielectric properties of a polycycloolefin resin and the wiring dimensions for the models, the values of FIG. 12 were used. The line resistivity is given by ρ=1.72 μΩ-cm and an increase in line loss due to surface roughness is not taken into account. The measurement results and the calculation results of the high-frequency RLGC models well agree with each other for the respective film thicknesses and thus it is seen that the roughness of the dielectric-metal interface or the resin film interface due to the lamination of the dielectric resin films does not affect the propagation characteristics.

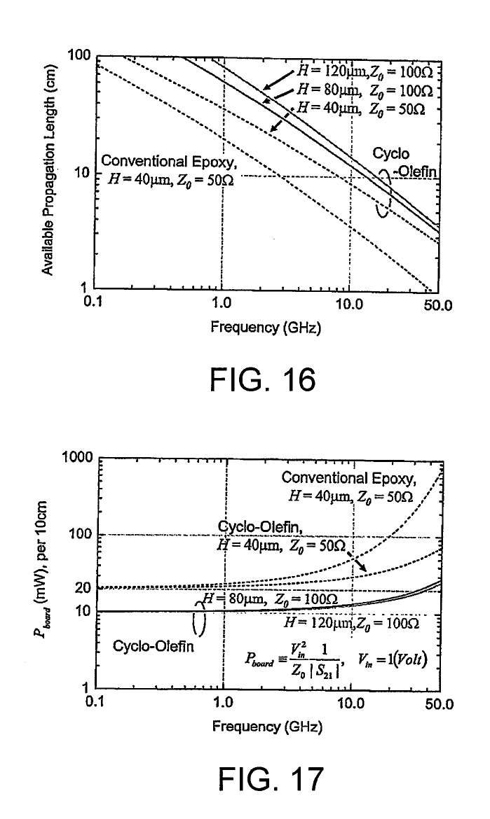

FIG. 16 shows the available propagation length calculated from the propagation characteristics of the microstrip lines manufactured in the fourth comparative example 4. The available propagation length is defined as a signal propagation length where /S21/ becomes −3 dB or less. In comparison for a propagation length of 10 cm which is generally required in a printed wiring board, it was demonstrated that propagation of an ultrahigh frequency such as fp=13.0 GHz with H2=80 μm and Z0=100Ω or fp=16.1 GHz with H2′=120 μm and Z0=100Ω was enabled.

FIG. 17 shows the consumption power in propagation for 10 cm per wiring calculated from the propagation characteristics described above. By increasing the characteristic impedance Z0 to 100Ω and reducing the propagation loss, the consumption power per wiring when a 10 GHz signal propagated for 10 cm was P_{board}=13.3 mW in the case of H2=80 μm and Z0=100Ω or P_{board}=120.6 mW in the case of H2′=120 μm and Z0=100Ω. Therefore, compared to a consumption power of 51.3 mW of a conventional microstrip line with H=40 μm and Z0=50Ω formed on an epoxy resin, the consumption power was suppressed to about ¼ and thus a large reduction in consumption power was achieved. It was confirmed that, also in the low-frequency region, it was possible to reduce the consumption power to ½ because the characteristic impedance was doubled.

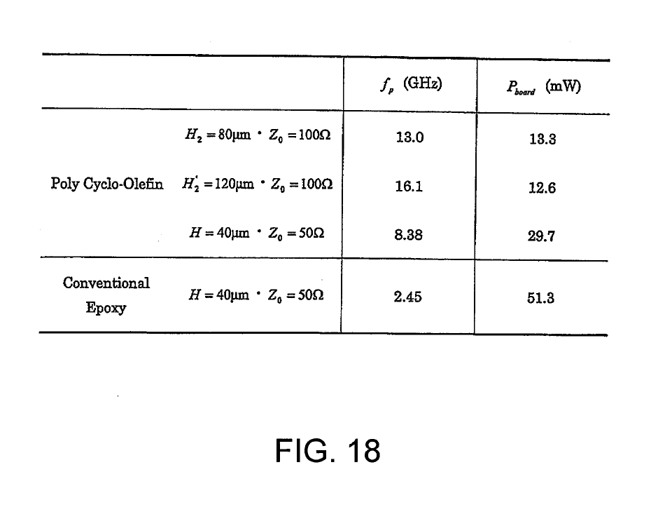

FIG. 18 shows the propagation characteristics of the microstrip lines, manufactured in the fourth comparative example 4, in terms of the frequency fp that enables propagation with a loss suppressed to −3 dB for a length of 10 cm, and the consumption power P_{board} per wiring while comparing with the conventional example. Using the wiring structure with the plurality of dielectric thicknesses mixed which uses, as the dielectric resin film, the low-permittivity, low-dielectric-loss polycycloolefin resin by employing the smooth plating technique, it is possible to realize an ultrahigh-frequency, low-consumption-power, high-density printed wiring board that can achieve propagation of a signal of 10 GHz or more with a low consumption power of ½ or less compared to conventional, while maintaining the mounting density.

In the above-mentioned first to fourth comparative examples 1 to 4, the excellent characteristics can be obtained as described above. However, the maximum propagation frequency is restricted to 16.1 GHz and, therefore, higher performance is required.

This invention is characterized by using, as a material of an insulating layer, a polymerizable composition material described in the specification of Japanese Patent Application No. 2009-294703.

Herein, the polymerizable composition material for use in this invention will be schematically described. As described in the specification of Japanese Patent Application No. 2009-294703, the polymerizable composition material contains a cycloolefin monomer, a polymerization catalyst, a cross-linking agent, a bifunctional compound having two vinylidene groups, and a trifunctional compound having three vinylidene groups, wherein the content ratio of the bifunctional compound and the trifunctional compound is 0.5 to 1.5 in terms of a weight ratio value (bifunctional compound/trifunctional compound). A bifunctional methacrylate compound is preferable as the bifunctional compound and a trifunctional methacrylate compound is preferable as the trifunctional compound. If necessary, the polymerizable composition may be added with a filler, a polymerization adjuster, a polymerization reaction retardant, a chain transfer agent, an antiaging agent, and other compounding agents.

The above-mentioned cycloolefin monomer, polymerization catalyst, cross-linking agent, bifunctional compound, trifunctional compound, filler, polymerization adjuster, polymerization reaction retardant, chain transfer agent, antiaging agent, and other compounding agents will be described later.

This invention relates to a multilayer wiring board using, as an insulating layer, a resin material formed by bulk-polymerizing and cross-linking the polymerizable composition described in the specification of Japanese Patent Application No. 2009-294703 (hereinafter, this resin material will be abbreviated as X-L-1). As a result of measuring the electrical properties of this board, it has been seen that tan δ representing the dielectric loss properties is usually 0.0012 at 1 GHz at room temperature (25° C.) and thus is extremely small compared to that of Patent Document 2. Further, it has been seen that the above-mentioned resin material usually has a relative permittivity ∈ᵣ of 3.53. On the other hand, the board of Patent Document 2 has tan δ of 0.01 and a relative permittivity of 2.5 at 1 GHz.

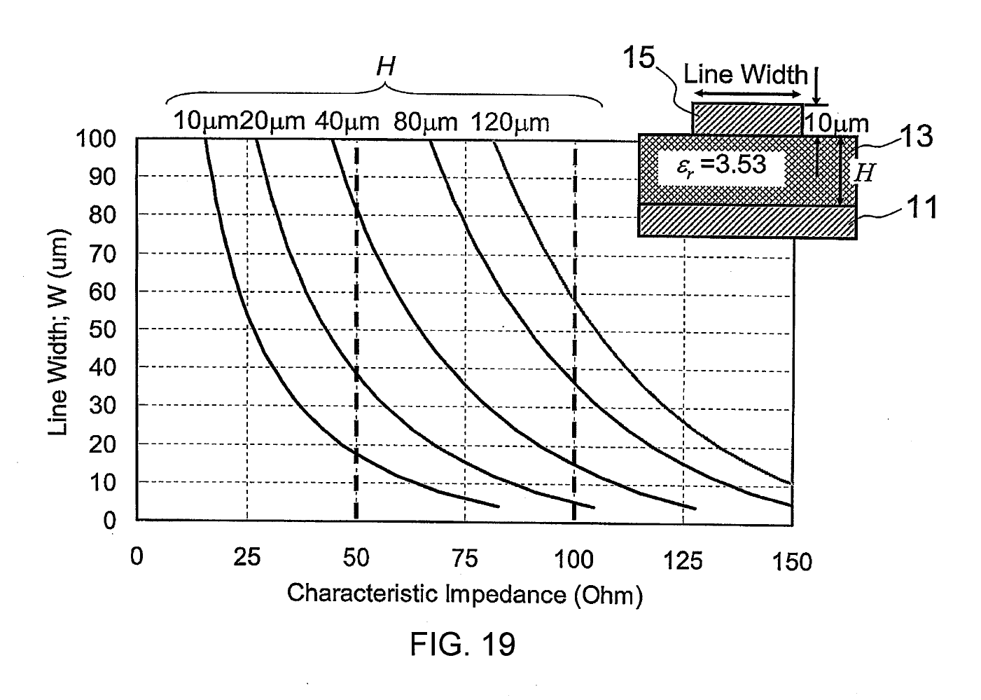

Referring to FIG. 19, there are shown relationships between the characteristic impedance and the width of a conductor layer when an insulating layer is formed of a resin material X-L-1 with a dissipation factor (tan δ) of 0.0012. In FIG. 19, as shown in the upper part of FIG. 19, measurement was carried out by manufacturing a microstrip line which comprises a conductor line 11 formed of copper, an insulating layer 13, as described above, with a thickness H formed on the conductor line 11, and a conductor line 15 with a width W and a thickness of 10 μm formed of copper on the insulating layer 13. Herein, the change in characteristic impedance was measured by changing the thickness (line height) H of the insulating layer 13 and the width W of the conductor line 15.

As is clear from FIG. 19, it is seen that as the thickness H of the insulating layer 13 increases, the characteristic impedance of the microstrip line increases, while, as the width W of the conductor line 15 decreases, the characteristic impedance increases.

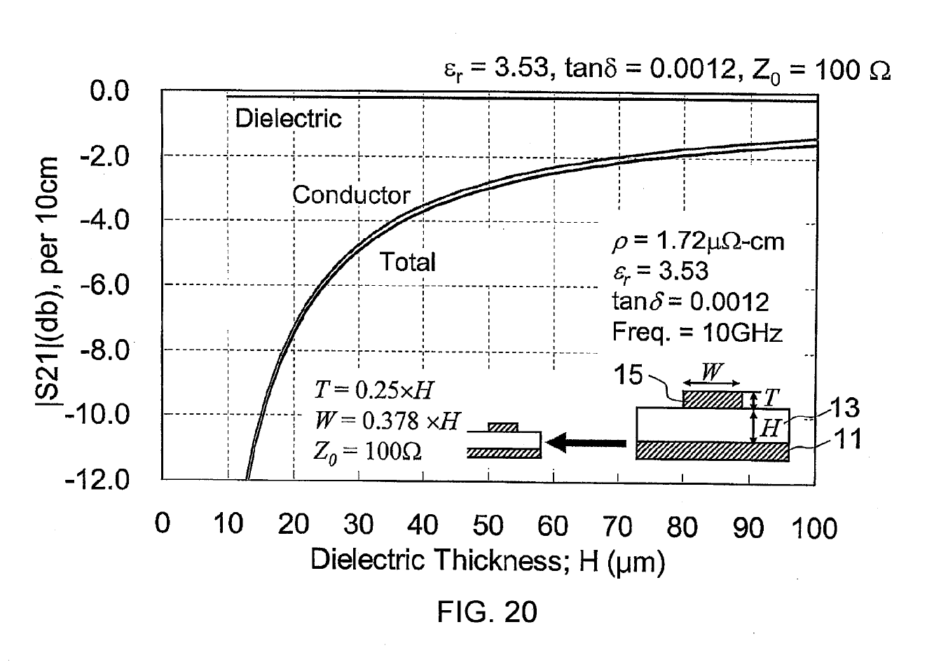

Referring to FIG. 20, there are shown changes in propagation loss S21 when the thickness H of an insulating layer formed of a resin material with tan δ of 0.0012 and a relative permittivity ∈ᵣ of 3.53 is changed and simultaneously the thickness T and the width W of a conductor line 15 are changed in relation to the thickness H of the insulating layer. Herein, in FIG. 20, the ordinate axis represents the propagation loss S21 per 10 cm and the abscissa axis represents the thickness H of the insulating layer, wherein a conductor line with an electrical specific resistance (resistivity) ρ of 1.72 μΩ·cm is used as the conductor line 15.

Herein, the propagation loss is shown when the height T of the conductor line 15 is set to be 0.25 times the thickness H of the insulating layer 13 and the width W of the conductor line 15 is set to be 0.378 times the thickness H of the insulating layer 13. In this case, the characteristic impedance Z0 of the microstrip line is 100Ω.

As is clear from FIG. 20, as the thickness H of the insulating layer 13 decreases, the propagation loss S21 of the conductor line 15 and the total propagation loss S21 of the microstrip line increase and, in particular, when the thickness H of the insulating layer 13 becomes less than 20 μm, the propagation loss S21 rapidly increases from −7 dB to −12 dB. On the other hand, FIG. 20 also shows that when the thickness H of the insulating layer 13 exceeds 50 μm, the propagation loss S21 can be suppressed to −3 dB or less. Accordingly, it is seen that when the thickness H of the insulating layer 13 is about 40 μm and the characteristic impedance Z0 is 100Ω, even if the width W and the thickness T of the wiring layer are set to as small as about 10 μm, it is possible to satisfactorily propagate a signal having a frequency of less than 10 GHz, for example, a signal having a frequency of 8 GHz.

According to a test by the present inventors, it was possible to change the characteristic impedance Z0 of the microstrip line by changing the width W of the conductor line 15 in the state where the thickness H of the insulating layer 13 with tan δ of 0.0012 and a relative permittivity ∈ᵣ of 3.53 was fixed to 130 μm and the thickness T of the conductor line 15 was fixed to 15 μm. For example, when the thickness T and the width W of the conductor line 15 were respectively set to 15 μm and 276 μm, the characteristic impedance Z0 was 50Ω.

Further, in the state where the thickness H of the insulating layer 13 was fixed to 130 μm, when the thickness T and the width W of the conductor line 15 were respectively set to 15 μm and 276 μm, the characteristic impedance Z0 was 100Ω, while, when the thickness T and the width W of the conductor line 15 were respectively set to 15 μm and 8.3 μm, the characteristic impedance Z0 was 150Ω.

Further, when the width W of the conductor line 15 was set to 10 μm or 20 μm in the state where the thickness H of the insulating layer 13 was fixed to 130 μm and the thickness T of the conductor line 15 was fixed to 15 μm, the characteristic impedance Z0 was 147.5Ω or 131.9Ω.

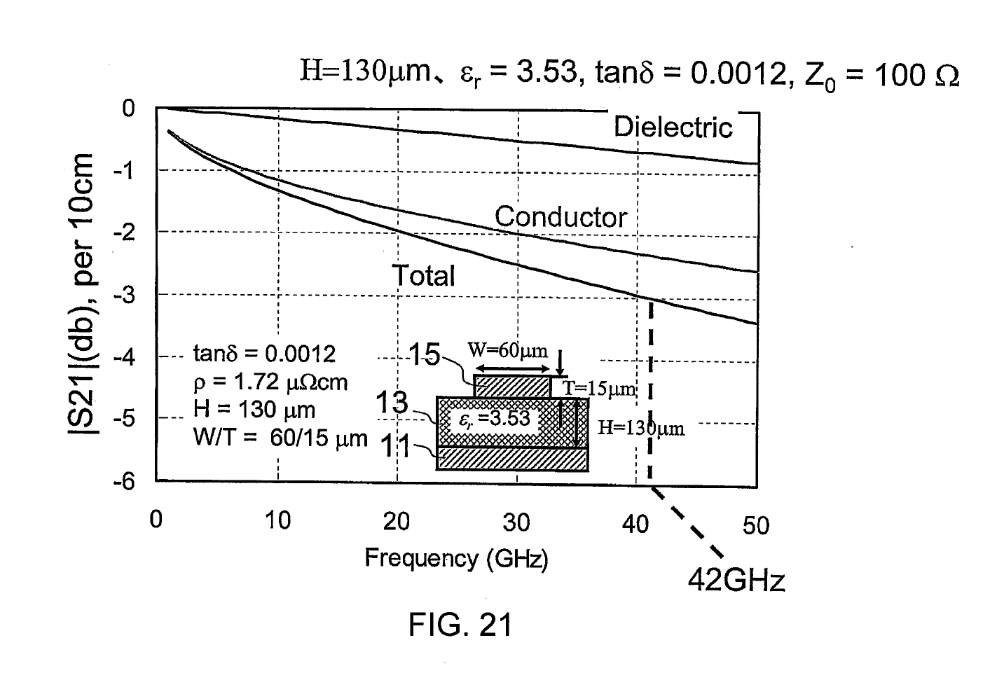

Referring to FIG. 21, there are shown propagation characteristics of a microstrip line when the thickness H of an insulating layer 13 is 130 μm and the thickness T and the width W of a conductor line 15 are respectively 15 μm and 60 μm. In FIG. 21, the abscissa axis represents the frequency (GHz) while the ordinate axis represents the propagation loss S21 per 10 cm. In this case, it is seen that the total propagation loss S21 of the microstrip line is maintained at −3 dB or less at 42 GHz or less and thus that signal propagation can be achieved with a low propagation loss up to an extremely high frequency range exceeding 40 GHz.

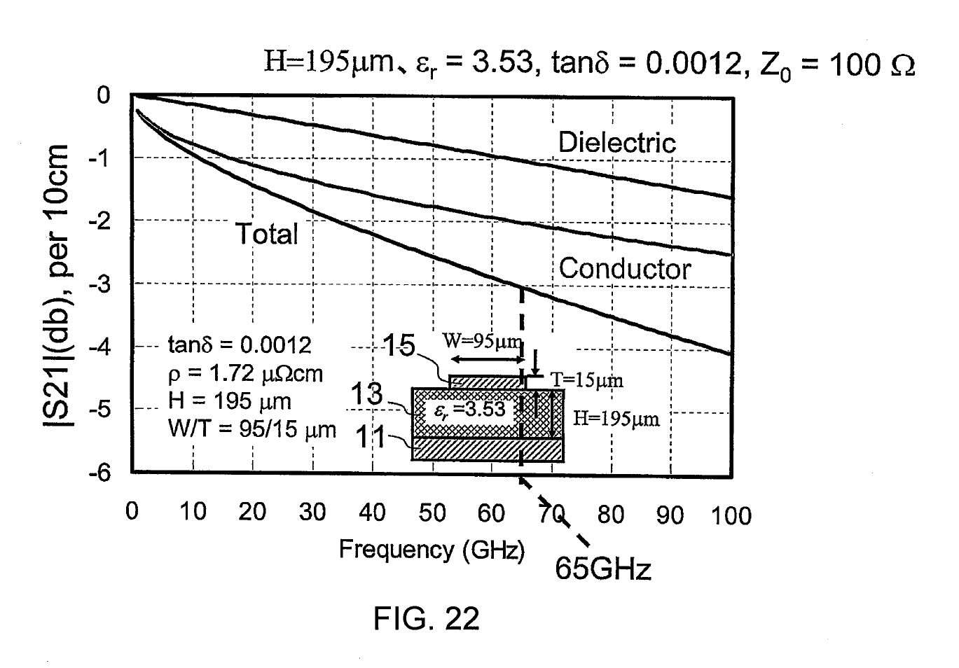

Next, referring to FIG. 22, there are shown propagation characteristics of a microstrip line when the thickness H of an insulating layer 13 is set greater than that in FIG. 21. Also in FIG. 22, like in FIG. 21, the abscissa axis represents the frequency (GHz) while the ordinate axis represents the propagation loss S21 per 10 cm. Specifically, FIG. 22 shows the propagation characteristics when the thickness H of the insulating layer 13 is increased to 195 μm. The thickness T and the width W of a conductor line 15 are respectively 15 μm and 95 μm. That is, FIG. 22 shows the propagation characteristics of the microstrip line when the thickness H of the insulating layer 13 is set greater by 65 μm than in FIG. 21 and the width W of the conductor line 15 is set greater. As is clear from FIG. 22, it is seen that the total propagation loss of the microstrip line can be maintained at −3 dB or less up to 65 GHz.

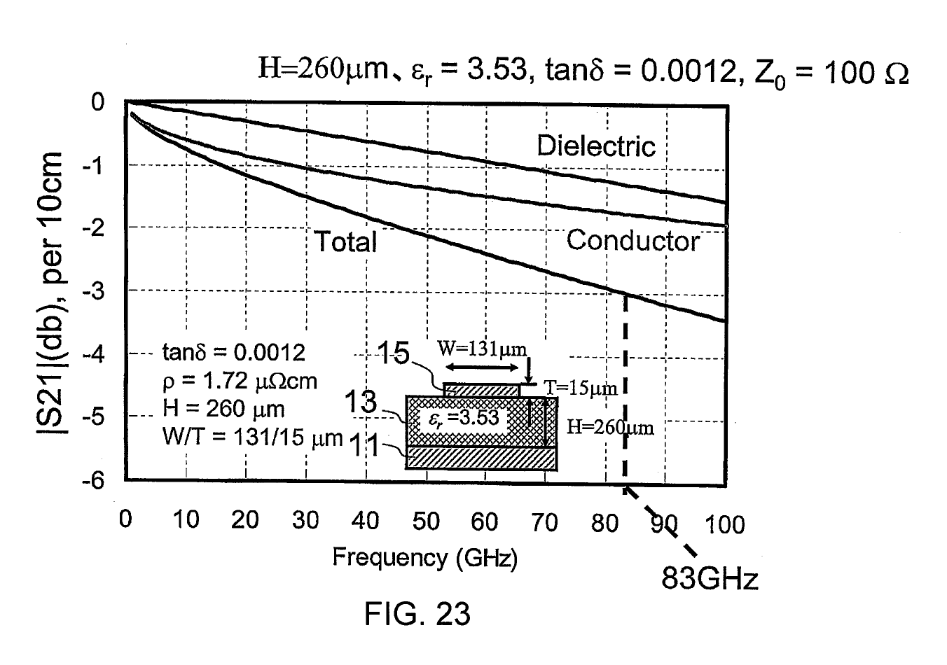

Further, referring to FIG. 23, there are shown propagation characteristics of a microstrip line which is similar to those in FIGS. 21 and 22. Herein, there is shown a case where the thickness of a conductor line 15 is set to 15 μm as in FIGS. 21 and 22 while the thickness H of an insulating layer 13 and the width W of the conductor line 15 are respectively set to 260 μm and 131 μm. As is clear from FIG. 23, the propagation loss per 10 cm can be maintained at −3 dB or less up to 83 GHz.

From FIGS. 21 to 23, it is seen that signal propagation can be achieved up to high frequencies by increasing the thickness H of the insulating layer 13 and the width W of the conductor line 15. Specifically, when the thickness H of the insulating layer 13 is set to about 65 μm and the thickness T and the width W of the wiring layer 15 are respectively set to about 15 μm and about 10 μm, the maximum frequency of at least 8 GHz is obtained and, when the thickness H of the insulating layer 13 is increased to 130 μm, the maximum frequency of 40 GHz or more is obtained. Further, when the thickness H of the insulating layer 13 is increased to 195 μm or 260 μm, the maximum frequency of 60 GHz or more or 80 GHz or more is obtained.

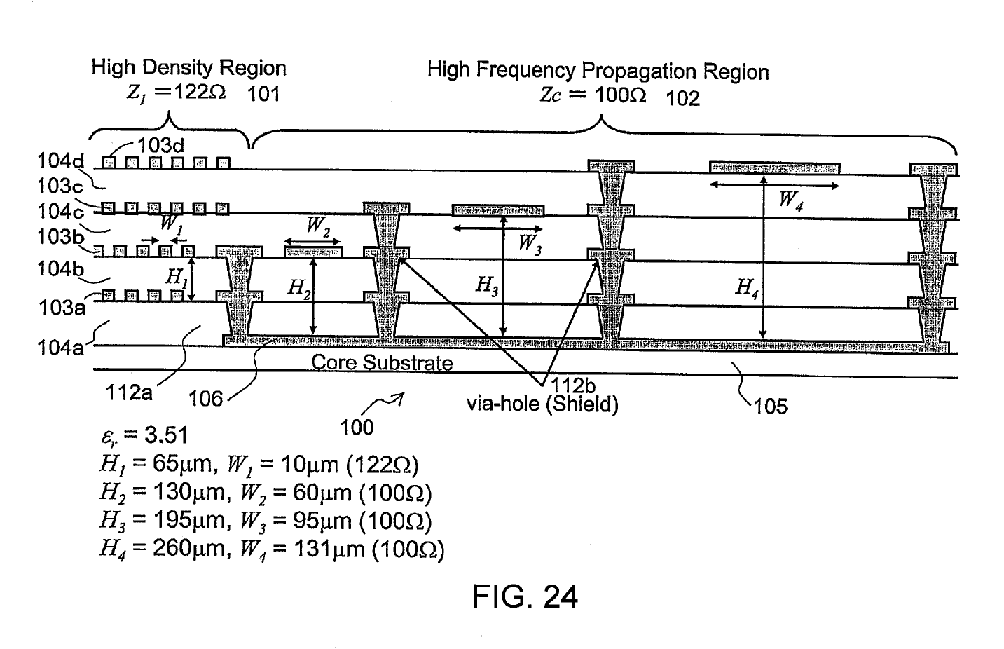

Referring to FIG. 24, there is shown a multilayer wiring board according to an embodiment of this invention. The illustrated multilayer wiring board 100 can be called a high-impedance printed wiring board with a plurality of dielectric thicknesses mixed and its structure has, in the single printed wiring board 100, regions that can respectively propagate ultrahigh-frequency signals in a GHz band, particularly of 40 GHz or more, 60 GHz or more, and 80 GHz or more with a low consumption power, while suppressing a reduction in mounting density to minimum.

Specifically, the illustrated multilayer wiring board 100 is apparently divided into a high-density region 101 and a high-frequency propagation region 102. Herein, the high-frequency propagation region 102 is a region that propagates a high-frequency signal usually exceeding 8 GHz, for example, a signal having a frequency of 40 GHz or more, while, the high-density region 101 is a region that propagates a low-frequency signal of usually 8 GHz or less, for example, a signal having a frequency of less than 8 GHz.

The high-density region 101 and the high-frequency propagation region 102 are provided on a single substrate 105, for example, a ground electrode or a printed board. In the high-density region 101, a first insulating layer 104a with tan δ of 0.0012 and a relative permittivity ∈ᵣ of 3.53 and a first wiring layer 103a formed of copper or the like are provided on the single substrate 105. Further, on the first wiring layer 103a, a second insulating layer 104b and a second wiring layer 103b are formed and, likewise, a third insulating layer 104c, a third wiring layer 103c, a fourth insulating layer 104d, and a fourth wiring layer 103d are laminated in this order. In the illustrated example, a description will be given assuming that the first to fourth insulating layers 104a to 104d are formed of the above-mentioned resin with tan δ of 0.0012 and a relative permittivity ∈ᵣ of 3.53, i.e. the resin material (X-L-1).

In the high-density region 101, the insulating layers 104 and the wiring layers 103 are alternately formed. Herein, a thickness H of each of the insulating layers 104a to 104d is 65 μm and a thickness T and a width W1 of each of the wiring layers 103a to 103d are respectively 15 μm and 10 μm. Further, the distance between patterns forming each of the wiring layers 103a to 103d is also about 10 μm. In this case, a characteristic impedance Z1 in the high-density region 101 is 122Ω.

On the other hand, in the high-frequency propagation region 102, the distances between wiring layers in a thickness direction and between wiring patterns in a lateral direction in each wiring layer are set greater than those in the high-density region 101. Insulating layers in the high-frequency propagation region 102 are formed of the above-mentioned resin material (X-L-1). The high-frequency propagation region 102 shown in FIG. 24 includes a plurality of noise shields that are electrically connected to a land 106 provided on the substrate 105. In the illustrated example, a via-hole conductor 112a reaching the land 106 from a surface of the second insulating layer 104b is provided in the boundary between the high-frequency propagation region 102 and the high-density region 101 and operates as a noise shield. That is, by providing the via-hole conductor 112a, it is possible to reduce electrical signal coupling between the wirings in the high-density region 101 and the high-frequency propagation region 102, thereby suppressing crosstalk noise that is superimposed on propagation signals.

On the second insulating layer 104b in the high-frequency propagation region 102, a second wiring layer 103b having a width W of 60 μm is provided. The second wiring layer 103b in the high-frequency propagation region 102 is provided at a position away from the land 106 by a distance of 130 μm. A pattern forming the second wiring layer 103b having the width W2 of 60 μm has a characteristic impedance of 100Ω.

Further, on the third insulating layer 104c and the fourth insulating layer 104d in the high-frequency propagation region 102, third and fourth wiring layers 103c and 103d respectively including patterns of a width W3 and a width W4 are provided. The wiring patterns of the third and fourth wiring layers 103c and 103d respectively have the width W3 of 95 μm and the width W4 of 131 μm and are respectively provided on the third and fourth insulating layers 104c and 104d which respectively have a thickness H3 and a thickness H4. In the illustrated example, the thickness H3 and the thickness H4 are respectively 195 μm and 260 μm. Patterns of the third and fourth wiring layers 103c and 103d each have a characteristic impedance of 100Ω. From this, it is seen that all the characteristic impedances Z0 of the second to fourth wiring layers 103b to 103d in the high-frequency propagation region 102 are 100Ω.

Referring further to FIG. 24, via-hole conductors 112b are respectively provided as noise shields between the second wiring layer 103b and the third wiring layer 103d in the high-frequency propagation region 102 and between the third wiring layer 103c and the fourth wiring layer 103d in the high-frequency propagation region 102. By providing the via-hole conductors 112b, it is possible to suppress crosstalk noise between the third wiring layer 103c and the fourth wiring layer 103d.

Features of the illustrated high-impedance printed wiring board with the plurality of dielectric thicknesses mixed are summarized as follows.

The single printed wiring board 100 has the high-density mounting region 101 for propagating a low-frequency DC power supply of, for example, 8 GHz or less and the high-frequency propagation region 102 that can achieve high-frequency propagation exceeding 80 GH with a low loss.

The illustrated high-frequency propagation region 102 has the first portion, the second portion, and the third portion. In order to suppress the line metal loss, the dielectric film thickness is, at the first portion, twice (H2=2×H1) or more the thickness of the insulating layer in the high-density mounting region 101, is three times (H2′=3×H1) or more at the second portion, and is four times or more at the third portion. Consequently, the first to third portions of the high-frequency propagation region 102 respectively have maximum frequencies exceeding 40 GHz, 60 GHz, and 80 GHz.

The insulating layer thicknesses shown in FIG. 24 can be achieved by applying a build-up multilayer printed wiring board forming method.

That is, a plated copper wiring on a lower-layer dielectric resin film in the high-frequency propagation region 102 is removed by etching during wiring patterning and then second-layer, third-layer, and fourth-layer resin films are built up thereon, thereby achieving the insulating layer thicknesses without newly introducing any special process.

Since the build-up multilayer printed wiring board forming method itself is the same as that described before, description thereof is omitted herein.

The characteristic impedance Z of the high-frequency propagation region 102 is preferably set to 100Ω or more. This is for reducing the consumption power and suppressing an increase in line width following the increase in dielectric resin film thickness to thereby improve the mounting density.

This invention is not limited to the above-mentioned embodiment and can be modified in various ways within the scope of this invention. For example, the wiring structure according to this invention can also be applied to wiring structures other than the microstrip line structure, for example, to a stripline structure and other multilayer wiring structures.

Next, the polymerizable composition material for use in this invention will be described. The polymerizable composition for use in this invention contains, as described before, the cycloolefin monomer, the polymerization catalyst, the cross-linking agent, the bifunctional compound having two vinylidene groups, and the trifunctional compound having three vinylidene groups.

Hereinbelow, the cycloolefin monomer, the polymerization catalyst, the cross-linking agent, the bifunctional compound, the trifunctional compound, and the like which are used in the above-mentioned polymerizable composition will be described.

Further, a cross-linkable resin shaped product which is formed by bulk-polymerizing the above-mentioned polymerizable composition and which is suitably used as a prepreg or the like, and a cross-linked resin shaped product which is formed by bulk-polymerizing and cross-linking the above-mentioned polymerizable composition will be described. An insulating layer according to this invention is made of such a cross-linked resin shaped product.

(Cycloolefin Monomer)

A cycloolefin monomer which is used in this invention is a compound that has an alicyclic structure formed by carbon atoms and has one polymerizable carbon-carbon double bond in the alicyclic structure. In this DESCRIPTION, a “polymerizable carbon-carbon double bond” represents a carbon-carbon double bond capable of chain polymerization (ring-opening polymerization). The ring-opening polymerization includes various types such as ion polymerization, radical polymerization, and metathesis polymerization, but in this invention, it usually represents the metathesis ring-opening polymerization.

As the alicyclic structure of the cycloolefin monomer, a monocyclic structure, a polycyclic structure, a condensed polycyclic structure, a bridged ring structure, polycyclic structures combining them, and the like can be given. The number of carbon atoms forming the alicyclic structure is not particularly limited, but is usually 4 to 30, preferably 5 to 20, and more preferably 5 to 15.

The cycloolefin monomer may have, as a substituent, a hydrocarbon group with a carbon number of 1 to 30 such as an alkyl group, alkenyl group, alkylidene group, or aryl group, or a polar group such as a carboxyl group or acid anhydride group. However, in terms of causing a laminate to be obtained to have a low dissipation factor, it is preferable that the cycloolefin monomer have no polar group, i.e. comprise only carbon atoms and hydrogen atoms.

As the cycloolefin monomer, it is possible to use either of a monocyclic cycloolefin monomer and a polycyclic cycloolefin monomer. In terms of highly balancing the dielectric properties and heat resistance properties of the laminate to be obtained, the polycyclic cycloolefin monomer is preferable. As the polycyclic cycloolefin monomer, in particular, a norbornene-based monomer is preferable.

A “norbornene-based monomer” represents a cycloolefin monomer having a norbornene ring structure in its molecule. For example, norbornenes, dicyclopentadienes, tetracyclododecenes, and the like can be given.

As the cycloolefin monomer, it is possible to use either of one having no cross-linkable carbon-carbon unsaturated bond and one having one or more cross-linkable carbon-carbon unsaturated bonds.

In this DESCRIPTION, a “cross-linkable carbon-carbon unsaturated bond” represents a carbon-carbon unsaturated bond that does not participate in a ring-opening polymerization, but can participate in a cross-linking reaction. The cross-linking reaction is a reaction that forms a cross-linked structure, and includes various types such as a condensation reaction, addition reaction, radical reaction, and metathesis reaction. Herein, it usually represents the radical cross-linking reaction or the metathesis cross-linking reaction, particularly the radical cross-linking reaction. As the cross-linkable carbon-carbon unsaturated bond, a carbon-carbon unsaturated bond other than an aromatic carbon-carbon unsaturated bond, i.e. an aliphatic carbon-carbon double bond or triple bond, can be given. Herein, it represents the aliphatic carbon-carbon double bond. In the cycloolefin monomer having one or more cross-linkable carbon-carbon unsaturated bonds, the position of the unsaturated bond is not particularly limited. In addition to the inside of the alicyclic structure formed by the carbon atoms, the unsaturated bond may be present at an arbitrary position other than the alicyclic structure, for example, at the terminal or inside of a side chain. For example, the aliphatic carbon-carbon double bond can be present as a vinyl group (CH₂═CH—), a vinylidene group (CH₂═C<), or a vinylene group (—CH═CH—) and exhibits excellent radical cross-linking reactivity, and therefore, it is preferably present as a vinyl group and/or a vinylidene group and more preferably as a vinylidene group.

As the cycloolefin monomer having no cross-linkable carbon-carbon unsaturated bond, for example, monocyclic cycloolefin monomers such as cyclopentene, 3-methylcyclopentene, 4-methylcyclopentene, 3,4-dimethylcyclopentene, 3,5-dimethylcyclopentene, 3-chlorocyclopentene, cyclohexene, 3-methylcyclohexene, 4-methylcyclohexene, 3,4-dimethylcyclohexene, 3-chlorocyclohexene, and cycloheptene; and norbornene-based monomers such as norbornene, 5-methyl-2-norbornene, 5-ethyl-2-norbornene, 5-propyl-2-norbornene, 5,6-dimethyl-2-norbornene, 1-methyl-2-norbornene, 7-methyl-2-norbornene, 5,5,6-trimethyl-2-norbornene, 5-phenyl-2-norbornene, tetracyclododecene, tricyclo[5.2.1.0^{2,6}]deca-3,8-dien (DCP), 1,4,5,8-dimethano-1,2,3,4,4a,5,8,8a-octahydronaphthalene (TCD), 1,4,4a,9a-tetrahydro-1,4-methanofluorene (MTF), 2-methyl-1,4,5,8-dimethano-1,2,3,4,4a,5,8,8a-octahydronaphthalene, 2-ethyl-1,4,5,8-dimethano-1,2,3,4,4a,5,8,8a-octahydronaphthalene, 2,3-dimethyl-1,4,5,8-dimethano-1,2,3,4,4a,5,8,8a-octahydronaphthalene, 2-hexyl-1,4,5,8-dimethano-1,2,3,4,4a,5,8,8a-octahydronaphthalene, 2-ethylidene-1,4,5,8-dimethano-1,2,3,4,4a,5,8,8a-octahydronaphthalene, 2-fluoro-1,4,5,8-dimethano-1,2,3,4,4a,5,8,8a-octahydronaphthalene, 2-ethylidene-1,2,3,4,4a,5,8,8a-octahydro-1,4:5,8-dimethanonaphthalene (ETD), 1,5-dimethyl-1,4,5,8-dimethano-1,2,3,4,4a,5,8,8a-octahydronaphthalene, 2-cyclohexyl-1,4,5,8-dimethano-1,2,3,4,4a,5,8,8a-octahydronaphthalene, 2,3-dichloro-1,4,5,8-dimethano-1,2,3,4,4a,5,8,8a-octahydronaphthalene, 2-isobutyl-1,4,5,8-dimethano-1,2,3,4,4a,5,8,8a-octahydronaphthalene, 1,2-dihydrodicyclopentadiene, 5-chloro-2-norbornene, 5,5-dichloro-2-norbornene, 5-fluoro-2-norbornene, 5,5,6-trifluoro-6-trifluoromethyl-2-norbornene, 5-chloromethyl-2-norbornene, 5-methoxy-2-norbornene, 5,6-dicarboxyl-2-norbornene anhydrate, 5-dimethylamino-2-norbornene, and 5-cyano-2-norbornene can be given. The norbornene-based monomers having no cross-linkable carbon-carbon unsaturated bond are preferable.

As the cycloolefin monomer having one or more cross-linkable carbon-carbon unsaturated bonds, for example, monocyclic cycloolefin monomers such as 3-vinylcyclohexene, 4-vinylcyclohexene, 1,3-cyclopentadiene, 1,3-cyclohexadiene, 1,4-cyclohexadiene, 5-ethyl-1,3-cyclohexadiene, 1,3-cycloheptadiene, and 1,3-cyclooctadiene; and norbornene-based monomers such as 5-ethylidene-2-norbornene, 5-methylidene-2-norbornene, 5-isopropylidene-2-norbornene, 5-vinyl-2-norbornene, 5-allyl-2-norbornene, 5,6-diethylidene-2-norbornene, dicyclopentadiene, and 2,5-norbornadiene can be given. The norbornene-based monomers having one or more cross-linkable carbon-carbon unsaturated bonds are preferable.

These cycloolefin monomers may be used alone or in combination of two or more kinds.

The cycloolefin monomer which is used in a polymerizable composition of this invention preferably contains a cycloolefin monomer having one or more cross-linkable carbon-carbon unsaturated bonds. If such a cycloolefin monomer is used, the reliability of the laminate to be obtained is improved, which is thus preferable.

In the cycloolefin monomer which is mixed into the polymerizable composition of this invention, the mixing ratio of a cycloolefin monomer having one or more cross-linkable carbon-carbon unsaturated bonds and a cycloolefin monomer having no cross-linkable carbon-carbon unsaturated bond may be suitably selected as desired, but is usually in a range of 5/95 to 100/0, preferably 10/90 to 90/10, and more preferably 15/85 to 70/30 in terms of a weight ratio value (cycloolefin monomer having one or more cross-linkable carbon-carbon unsaturated bonds/cycloolefin monomer having no cross-linkable carbon-carbon unsaturated bond). If the mixing ratio is in such a range, the heat resistance can be highly improved in the laminate to be obtained, which is thus preferable.

As long as the effect of this invention is not impaired, the polymerizable composition of this invention may optionally contain a monomer which is copolymerizable with the above-mentioned cycloolefin monomer.

(Polymerization Catalyst)

A polymerization catalyst which is used in this invention is not particularly limited as long as it can polymerize the above-mentioned cycloolefin monomer. However, the polymerizable composition of this invention is preferably directly subjected to bulk polymerization in the manufacture of a later-described cross-linkable resin shaped product. Therefore, usually, it is preferable to use a metathesis polymerization catalyst.

As the metathesis polymerization catalyst, a complex which enables metathesis ring-opening polymerization of the above-mentioned cycloolefin monomer and in which, usually, ions, atoms, polyatomic ions, compounds, and the like are bonded around a transition metal atom as a center atom can be given. As the transition metal atom, an atom of group V, group VI, or group VIII (according to the long-form periodic table, the same shall apply hereinafter) is used. The atom of each group is not particularly limited, while, for example, tantalum can be given as an atom of group V, molybdenum or tungsten can be given as an atom of group VI, and ruthenium or osmium can be given as an atom of group VIII. Of these, ruthenium or osmium of group VIII is preferable as the transition metal atom. That is, as the metathesis polymerization catalyst which is used in this invention, a complex having ruthenium or osmium as a center atom is preferable, while a complex having ruthenium as a center atom is more preferable. As the complex having ruthenium as the center atom, a ruthenium-carbene complex having a carbene compound coordinated to ruthenium is preferable. Herein, a “carbene compound” is a general term for a compound having a methylene free group and represents a compound having a bivalent carbon atom (carbine carbon) with no charge as expressed by (>C:). The ruthenium-carbene complex is excellent in catalytic activity in bulk polymerization. Therefore, when the polymerizable composition of this invention is subjected to bulk polymerization to obtain a cross-linkable resin shaped product, the obtained shaped product has little odor due to unreacted monomer and the high-quality shaped product is obtained with high productivity. Further, since the ruthenium-carbene complex is relatively stable to oxygen and moisture in the air and thus is hardly deactivated, it can be used even in the atmosphere.

The metathesis polymerization catalyst is used alone or in combination of two or more kinds. The amount of use of the metathesis polymerization catalyst is usually in a range of 1:2,000 to 1:2,000,000, preferably 1:5,000 to 1:1,000,000, and more preferably 1:10,000 to 1:500,000 in terms of a molar ratio (metal atom in metathesis polymerization catalyst:cycloolefin monomer).

The metathesis polymerization catalyst if desired can be used dissolved or suspended in a small amount of an inert solvent. As the solvent, chain aliphatic hydrocarbons such as n-pentane, n-hexane, n-heptane, liquid paraffin, and mineral spirit; alicyclic hydrocarbons such as cyclopentane, cyclohexane, methylcyclohexane, dimethylcyclohexane, trimethylcyclohexane, ethylcyclohexane, diethylcyclohexane, decahydronaphthalene, dicycloheptane, tricyclodecane, hexahydroindene, and cyclooctane; aromatic hydrocarbons such as benzene, toluene, and xylene; hydrocarbons having alicyclic and aromatic ring structures, such as indene and tetrahydronaphthalene; nitrogen-containing hydrocarbons such as nitromethane, nitrobenzene, and acetonitrile; oxygen-containing hydrocarbons such as diethylether and tetrahydrofuran; and the like can be given. Of these, the chain aliphatic hydrocarbons, the alicyclic hydrocarbons, the aromatic hydrocarbons, and the hydrocarbons having alicyclic and aromatic ring structures are preferably used.

(Cross-Linking Agent)

A cross-linking agent which is used in the polymerizable composition of this invention is used for the purpose of inducing a cross-linking reaction in a polymer (cycloolefin polymer) which is obtained by subjecting the polymerizable composition to a polymerization reaction. Therefore, the polymer can be a post cross-linkable thermoplastic resin. Herein, “post cross-linkable” means that the resin can be a cross-linked resin by a cross-linking reaction which proceeds by heating the resin. The cross-linkable resin shaped product having the above-mentioned polymer as a base resin melts by heating, but since it is high in viscosity, its shape is maintained, while when it is brought into contact with an arbitrary member, it follows at its surface the shape of the member and finally cross-links to cure. Such properties of the cross-linkable resin shaped product of this invention are considered to contribute to the interlayer adhesion and the wire embedding ability in a laminate which is obtained by laminating the cross-linkable resin shaped products and heating, melting, and cross-linking them.

The cross-linking agent which is used in the polymerizable composition of this invention is not particularly limited, but usually a radical generator is preferably used. As the radical generator, for example, an organic peroxide, a diazo compound, a nonpolar radical generator, and the like can be given. The organic peroxide and the nonpolar radical generator are preferable.

As the organic peroxide, for example, hydroperoxides such as t-butyl hydroperoxide, p-mentane hydroperoxide, and cumen hydroperoxide; dialkyl peroxides such as dicumyl peroxide, t-butylcumyl peroxide, α,α′-bis(t-butylperoxy-m-isopropyl)benzene, di-t-butylperoxide, 2,5-dimethyl-2,5-di(t-butylperoxy)-3-hexine, and 2,5-dimethyl-2,5-di(t-butylperoxy)hexane; diacyl peroxides such as dipropionyl peroxide and benzoyl peroxide; peroxyketals such as 2,2-di(t-butylperoxy)butane, 1,1-di(t-hexylperoxy)cyclohexane, 1,1-di(t-butylperoxy)-2-methylcyclohexane, and 1,1-di(t-butylperoxy)cyclohexane; peroxy esters such as t-butylperoxy acetate and t-butylperoxy benzoate; peroxy carbonates such as t-butylperoxyisopropyl carbonate and di(isopropylperoxy)dicarbonate; alkylsilyl peroxides such as t-butyltrimethylsilyl peroxide; and cyclic peroxides such as 3,3,5,7,7-pentamethyl-1,2,4-trioxepane, 3,6,9-triethyl-3,6,9-trimethyl-1,4,7-triperoxonane, and 3,6-diethyl-3,6-dimethyl-1,2,4,5-tetroxane can be given. Of these, the dialkyl peroxides, the peroxyketals, and the cyclic peroxides are preferable in terms of little obstruction to the polymerization reaction.

As the diazo compound, for example, 4,4′-bisazidobenzal(4-methyl)cyclohexanone, 2,6-bis(4′-azidobenzal)cyclohexanone, and the like can be given.

As the nonpolar radical generator, 2,3-dimethyl-2,3-diphenylbutane, 3,4-dimethyl-3,4-diphenylhexane, 1,1,2-triphenylethane, 1,1,1-triphenyl-2-phenylethane, and the like can be given.

When the radical generator is used as a cross-linking agent, the one-minute half-life temperature is suitably selected by the conditions of curing (cross-linking of a polymer obtained by subjecting the polymerizable composition of this invention to a polymerization reaction), but is usually in a range of 100 to 300° C., preferably 150 to 250° C., and more preferably 160 to 230° C. Herein, the one-minute half-life temperature is a temperature at which half of the radial generator decomposes in one minute. For the one-minute half-life temperature of radical generators, for example, catalogs or websites of radical generator manufactures (e.g. NOF Corporation) may be referred to.

The radical generator may be used alone or in combination of two or more kinds. The amount of the radical generator mixed into the polymerizable composition of this invention is, per 100 parts by weight of the cycloolefin monomer, usually in a range of 0.01 to 10 parts by weight, preferably 0.1 to 10 parts by weight, and more preferably 0.5 to 5 parts by weight.

(Cross-Linking Aid)

In the polymerizable composition according to this invention, a bifunctional compound having two vinylidene groups (hereinafter, it may be simply referred to as a bifunctional compound) and a trifunctional compound having three vinylidene groups (hereinafter, it may be simply referred to as a trifunctional compound) are used. These compounds serve as a cross-linking aid. These compounds do not participate in the ring-opening polymerization reaction, but, using the vinylidene groups, can participate in the cross-linking reaction induced by the cross-linking agent. In the polymerizable composition of this invention, the bifunctional compound and the trifunctional compound are used at a content ratio of 0.5 to 1.5 in terms of a weight ratio value (bifunctional compound/trifunctional compound).

As described above, the polymer that is obtained by subjecting the polymerizable composition of this invention to the polymerization reaction can be the post cross-linkable thermoplastic resin. The cross-linkable resin shaped product according to this invention has such a polymer as a base resin.

The bifunctional compound and the trifunctional compound according to this invention are both present in a substantially free state in the polymer forming the cross-linkable resin shaped product of this invention and therefore exhibit a plasticizing effect on the polymer. Accordingly, if the shaped product is heated, the polymer melts and exhibits suitable fluidity. On the other hand, if the shaped product continues to be heated, a cross-linking reaction is induced by the cross-linking agent. Since the bifunctional compound and the trifunctional compound each participate in the cross-linking reaction and exhibit binding reactivity with the polymer, it is presumed that as the cross-linking reaction proceeds, the bifunctional compound and the trifunctional compound which are present in the free state are reduced in amount and thus that there is substantially no bifunctional compound or trifunctional compound present in the free state at the completion of the cross-linking reaction. While the bifunctional compound and the trifunctional compound exhibit the above-mentioned properties, the binding reactivity with the polymer seems to be higher in the trifunctional compound than in the bifunctional compound and, therefore, the plasticizing effect can be exhibited longer by the bifunctional compound compared to the trifunctional compound. The cross-linking aid is used with the intention of increasing the cross-linking density in the laminate to be obtained to thereby improve the heat resistance of the laminate. However, if, during heating of the cross-linkable resin shaped product, a cross-linked structure is formed earlier in the polymer forming the shaped product, sufficient fluidity of the polymer cannot be obtained so that the follow-up ability of the surface of the cross-linkable resin shaped product to other members decreases. In this regard, if the bifunctional compound and the trifunctional compound are jointly used, even after the plasticizing effect by the trifunctional compound disappears in the polymer, the plasticizing effect by the bifunctional compound can be expected to continue and thus the follow-up ability can be suitably exhibited in the cross-linkable resin shaped product, while the cross-linking density of the base resin is improved as the cross-linking proceeds. Presumably, since the predetermined bifunctional compound and trifunctional compound are jointly used at the above-mentioned ratio in the polymerizable composition of this invention, in the laminate to be obtained, the interlayer adhesion between the base resin and the other members is improved and, in addition thereto, suitably high cross-linking density is obtained in the base resin and thus, in general, the peel strength increases and the heat resistance is also improved.

If the content ratio of the bifunctional compound and the trifunctional compound is less than 0.5, sufficient peel strength cannot be obtained in the laminate to be obtained, while if the content ratio of the bifunctional compound and the trifunctional compound exceeds 1.5, the heat resistance becomes insufficient in the laminate.

In the bifunctional compound and the trifunctional compound forming the polymerizable composition of this invention, since the vinylidene group is excellent in cross-linking reaction, it is preferably present as an isopropenyl group or a methacryl group and is more preferably present as a methacryl group.

As specific examples of the bifunctional compound having two vinylidene groups, bifunctional compounds having two isopropenyl groups, such as p-diisopropenylbenzene, m-diisopropenylbenzene, and o-diisopropenylbenzene; bifunctional compounds having two methacryl groups, such as ethylene dimethacrylate, 1,3-butylene dimethacrylate, 1,4-butylene dimethacrylate, 1,6-hexanediol dimethacrylate, polyethyleneglycol dimethacrylate, polyethyleneglycol dimethacrylate, ethyleneglycol dimethacrylate, triethyleneglycol dimethacrylate, diethyleneglycol dimethacrylate, and 2,2′-bis(4-methacryloxydiethoxyphenyl)propane; and the like can be given. As the bifunctional compound having two vinylidene groups, the bifunctional compounds having two methacryl groups (bifunctional methacrylate compounds) are preferable.

As specific examples of the trifunctional compound having three vinylidene groups, trifunctional compounds having three methacryl groups, such as trimethylolpropane trimethacrylate and pentaerythritol trimethacrylate; and the like can be given. As the trifunctional compound having three vinylidene groups, the trifunctional compounds having three methacryl groups (trifunctional methacrylate compounds) are preferable.

In the polymerizable composition according to this invention, it is particularly preferable to use the bifunctional methacrylate compound and the trifunctional methacrylate compound in combination. According to such a combination, in the cross-linkable resin shaped product, the resin fluidity at the time of heating and curing is improved so that the follow-up ability of the surface of the shaped product to the other members is enhanced, while, in the laminate, the peel strength and the heat resistance are highly balanced, which is thus quite preferable.

In terms of increasing the resin fluidity of the cross-linkable resin shaped product to be obtained and improving the heat resistance of the laminate to be obtained, the content ratio of the bifunctional compound and the trifunctional compound in the polymerizable composition of this invention is preferably 0.7 to 1.4 and more preferably 0.8 to 1.3 in terms of a weight ratio value (bifunctional compound/trifunctional compound).

Each of the bifunctional compound and the trifunctional compound may be used alone or in combination of two or more kinds. In terms of maintaining good the dissipation factor of the laminate to be obtained, the total amount of the bifunctional compound and the trifunctional compound mixed into the polymerizable composition of this invention is, per 100 parts by weight of the cycloolefin monomer, usually 0.1 to 100 parts by weight, preferably 0.5 to 50 parts by weight, and more preferably 1 to 30 parts by weight.

As long as the effect of this invention is not impaired, the polymerizable composition of this invention may contain, for example, another cross-linking aid such as triallyl cyanurate.

(Polymerizable Composition)

The polymerizable composition according to this invention contains the above-mentioned cycloolefin monomer, polymerization catalyst, cross-linking agent, bifunctional compound, and trifunctional compound as essential components and, as desired, may be added with a filler, a polymerization adjuster, a polymerization reaction retardant, a chain transfer agent, an antiaging agent, and other compounding agents.

In this invention, a filler is preferably mixed into the polymerizable composition in terms of enhancing the function of the laminate. The polymerizable composition according to this invention is lower in viscosity compared to a polymer varnish obtained by dissolving an epoxy resin or the like in a solvent and conventionally used in the manufacture of a prepreg or a laminate, and therefore, the filler can be easily mixed therein at a high ratio. Accordingly, the cross-linkable resin shaped product or the laminate to be obtained may contain the filler exceeding the limit content of the conventional prepreg or laminate.

As the filler, either of an organic filler and an inorganic filler can be used. The filler may be suitably selected as desired, but usually the inorganic filler is preferably used. As the inorganic filler, for example, a low linear expansion filler and a nonhalogen flame retardant can be given.

The low linear expansion filler is an inorganic filler with a generally low linear expansion coefficient. By mixing it in the polymerizable composition of this invention, the mechanical strength is improved and the linear expansion coefficient can be lowered in the laminate to be obtained, which is thus preferable.

The linear expansion coefficient of the low linear expansion filler is usually 15 ppm/° C. or less. The linear expansion coefficient of the low linear expansion filler can be measured by a thermal mechanical analyzer (TMA). As such a low linear expansion filler, any one which is industrially used can be used without particular limitation. For example, inorganic oxides such as silica, silica balloon, alumina, iron oxide, zinc oxide, magnesium oxide, tin oxide, beryllium oxide, barium ferrite, and strontium ferrite; inorganic carbonates such as calcium carbonate, magnesium carbonate, and sodium hydrogen carbonate; inorganic sulfates such as calcium sulfate; inorganic silicates such as talc, clay, mica, kaolin, fly ash, montmorillonite, calcium silicate, glass, glass balloon; and the like can be given. Silica is preferable.

The nonhalogen flame retardant comprises a flame retardant compound containing no halogen atom. By mixing it in the polymerizable composition of this invention, the flame retardancy of the laminate to be obtained can be improved and further there is no concern about the production of dioxin when burning the laminate, which is thus preferable. As the nonhalogen flame retardant, any one which is industrially used can be used without particular limitation. For example, metal hydroxide flame retardants such as aluminum hydroxide and magnesium hydroxide; phosphinate flame retardants such as aluminum dimethylphosphinate and aluminum diethylphosphinate; metal oxide flame retardants such as magnesium oxide and aluminum oxide; phosphorus-containing flame retardants other than phosphinates, such as triphenyl phosphate, tricresyl phosphate, trixylenyl phosphate, cresyl diphenylphosphate, resorcinol bis(diphenyl)phosphate, bisphenol A bis(diphenyl)phosphate, and bisphenol A bis(dicresyl)phosphate; nitrogen-containing flame retardants such as melamine derivatives, guanidines, and isocyanules; flame retardants containing both phosphorus and nitrogen, such as polyammonium phosphate, melamine phosphate, polymelamine phosphate, polymelam phosphate, guanidine phosphate, and phosphazens; and the like can be given. As the nonhalogen flame retardants, the metal hydroxide flame retardants, the phosphinate flame retardants, and the phosphorus-containing flame retardants other than phosphinates are preferable. As the phosphorus-containing flame retardants, tricresyl phosphate, resorcinol bis(diphenyl)phosphate, bisphenol A bis(diphenyl)phosphate, and bisphenol A bis(dicresyl)phosphate are particularly preferable.

The particle size (average particle size) of the filler which is used in the polymerizable composition of this invention may be suitably selected as desired, but the average value of the lengths in long and short directions when observing particles three-dimensionally is usually in a range of 0.001 to 50 μm, preferably 0.01 to 10 μm, and more preferably 0.1 to 5 μm.

These fillers may be used alone or in combination of two or more kinds. The amount of the filler mixed into the polymerizable composition of this invention is, per 100 parts by weight of the cycloolefin monomer, usually in a range of 50 parts by weight or more, preferably 50 to 1,000 parts by weight, more preferably 50 to 750 parts by weight, and further preferably 100 to 500 parts by weight.

A polymerization adjuster is mixed for the purpose of controlling the polymerization activity or improving the polymerization reaction rate. For example, trialkoxy aluminum, triphenoxy aluminum, dialkoxyalkyl aluminum, alkoxydialkyl aluminum, trialkyl aluminum, dialkoxy aluminum chloride, alkoxyalkyl aluminum chloride, dialkyl aluminum chloride, trialkoxy scandium, tetraalkoxy titanium, tetraalkoxy tin, tetraalkoxy zirconium, and the like can be given. These polymerization adjusters may be used alone or in combination of two or more kinds. The mixing amount of the polymerization adjuster is, for example, usually in a range of 1:0.05 to 1:100, preferably 1:0.2 to 1:20, and more preferably 1:0.5 to 1:10 in terms of a molar ratio (metal atom in metathesis polymerization catalyst:polymerization adjuster).

A polymerization reaction retardant can suppress an increase in viscosity of the polymerizable composition of this invention. Therefore, the polymerizable composition mixed with the polymerization reaction retardant can be easily uniformly impregnated in a fiber reinforcing material when, for example, manufacturing a prepreg as a cross-linkable resin shaped product, which is thus preferable.

As the polymerization reaction retardant, it is possible to use a phosphine compound such as triphenyl phosphine, tributyl phosphine, trimethyl phosphine, triethyl phosphine, dicyclohexyl phosphine, vinyldiphenyl phosphine, allyldiphenyl phosphine, triallyl phosphine, or styryldiphenyl phosphine; a Lewis base such as aniline or pyridine; or the like. The mixing amount thereof may be suitably adjusted as desired.

A chain transfer agent if desired can be mixed into the polymerizable composition of this invention. Since the follow-up ability of the surface of the cross-linkable resin shaped product to be obtained can be improved at the time of heating and curing, the interlayer adhesion is enhanced in the laminate which is obtained by laminating such shaped products and heating, melting, and cross-linking them, which is thus preferable.

The chain transfer agent may have one or more cross-linkable carbon-carbon unsaturated bonds. As specific examples of the chain transfer agent, chain transfer agents having no cross-linkable carbon-carbon unsaturated bond, such as 1-hexene, 2-hexene, styrene, vinylcyclohexane, allylamine, glycidyl acrylate, allylglycidylether, ethylvinylether, methylvinylketone, 2-(diethylamino)ethyl acrylate, and 4-vinylaniline; chain transfer agents having one cross-linkable carbon-carbon unsaturated bond, such as divinylbenzene, vinyl methacrylate, allyl methacrylate, styryl methacrylate, allyl acrylate, undecenyl methacrylate, styryl acrylate, and ethyleneglycol diacrylate; chain transfer agents having two or more cross-linkable carbon-carbon unsaturated bonds, such as allyltrivinyl silane and allylmethyldivinyl silane; and the like can be given. Of these, in terms of highly balancing the peel strength and the heat resistance in the laminate to be obtained, the chain transfer agent having one or more cross-linkable carbon-carbon unsaturated bonds is preferable, while the chain transfer agent having one cross-linkable carbon-carbon unsaturated bond is more preferable. Of these chain transfer agents, the chain transfer agent having one vinyl group and one methacryl group is preferable, while vinyl methacrylate, allyl methacrylate, styryl methacrylate, undecenyl methacrylate, and the like are particularly preferable.

These chain transfer agents may be used alone or in combination of two or more kinds. In consideration of the balance between the peel strength and the heat resistance of the laminate to be obtained, the amount of the chain transfer agent mixed into the polymerizable composition of this invention is, per 100 parts by weight of the cycloolefin monomer, usually in a range of 0.01 to 10 parts by weight and preferably 0.1 to 5 parts by weight.

If, as an antiaging agent, at least one kind of antiaging agent selected from the group comprising a phenol-based antiaging agent, an amine-based antiaging agent, a phosphorus-based antiaging agent, and a sulfur-based antiaging agent is mixed, the heat resistance of the laminate to be obtained can be highly improved without inhibiting the cross-linking reaction, which is thus preferable. Of these, the phenol-based antiaging agent and the amine-based antiaging agent are preferable, while the phenol-based antiaging agent is more preferable. These antiaging agents may be used alone or in combination of two or more kinds. The amount of use of the antiaging agent is suitably selected as desired, but is, per 100 parts by weight of the cycloolefin monomer, usually in a range of 0.0001 to 10 parts by weight, preferably 0.001 to 5 parts by weight, and more preferably 0.01 to 2 parts by weight.

The polymerizable composition according to this invention may be mixed with other compounding agents. As the other compounding agents, it is possible to use a coloring agent, a photostabilizer, a foaming agent, and the like. As the coloring agent, a dye, a pigment, or the like may be used. There are various kinds of dyes and a known one may be suitably selected and used. These other compounding agents may be used alone or in combination of two or more kinds. The amount of use thereof is suitably selected in a range not impairing the effect as the polymerizable composition.

The polymerizable composition according to this invention can be obtained by mixing the above-mentioned components. A mixing method may follow an ordinary method. For example, the polymerizable composition can be prepared by dissolving or dispersing the polymerization catalyst in a suitable solvent to prepare a solution (catalyst solution), separately mixing the essential components such as the cycloolefin monomer and the cross-linking agent, and the other compounding agents as desired to prepare a solution (monomer solution), adding the catalyst solution to the monomer solution, and stirring them.

(Cross-Linkable Resin Shaped Product)

A cross-linkable resin shaped product according to this invention is obtained by bulk polymerization of the polymerizable composition. As a method of obtaining the cross-linkable resin shaped product by bulk-polymerizing the polymerizable composition, for example, (a) a method of coating the polymerizable composition on a support member and then bulk-polymerizing it, (b) a method of injecting the polymerizable composition in a shaping mold and then bulk-polymerizing it, (c) a method of impregnating the polymerizable composition in a fiber reinforcing material and then bulk-polymerizing it, and the like can be given.

The polymerizable composition used in this invention is low in viscosity. Therefore, in the method (a), the coating can be smoothly carried out, with the injection in the method (b), the polymerizable composition can quickly reach spaces of even complicated shapes without causing bubbles, and in the method (c), the polymerizable composition can be quickly and uniformly impregnated in the fiber reinforcing material.

According to the method (a), a cross-linkable resin shaped product having a film shape, a plate shape, or the like is obtained. The thickness of the shaped product is usually 15 mm or less, preferably 5 mm or less, more preferably 0.5 mm or less, and most preferably 0.1 mm or less. As the support member, for example, a film or a plate made of a resin such as polytetrafluoroethylene, polyethylene terephthalate, polypropylene, polyethylene, polycarbonate, polyethylene naphthalate, polyarylate, or nylon; a film or a plate made of a metal material such as iron, stainless steel, copper, aluminum, nickel, chrome, gold, or silver; or the like can be given. Of these, a metal foil or a resin film is preferably used. In terms of the workability and the like, the thickness of the metal foil or the resin film is usually 1 to 150 μm, preferably 2 to 100 μm, and more preferably 3 to 75 μm. As the metal foil, one with a smooth surface is preferable. The surface roughness (Rz) thereof is usually 10 μm or less, preferably 5 μm or less, more preferably 3 μm or less, and further preferably 2 μm or less in terms of a value measured by an AFM (atomic force microscope). If the surface roughness of the metal foil is in the above-mentioned range, the occurrence of noise, delay, propagation loss, or the like in high-frequency propagation can be suppressed in a high-frequency circuit board to be obtained, which is thus preferable. Further, the surface of the metal foil is preferably treated with a known coupling agent or binder such as a silane coupling agent, a thiol coupling agent, or a titanate coupling agent, or the like. According to the method (a), for example, when a copper foil is used as the support member, it is possible to obtain a resin-coated copper foil (RCC).

As the method of coating the polymerizable composition of this invention on the support member, known coating methods such as a spray coating method, a dip coating method, a roll coating method, a curtain coating method, a die coating method, and a slit coating method can be given.

The polymerizable composition coated on the support member is dried as desired and then bulk-polymerized. The bulk polymerization is carried out by heating the polymerizable composition at a predetermined temperature. A method of heating the polymerizable composition is not particularly limited. A method of placing on a heating plate the polymerizable composition coated on the support member and heating it, a method of heating it while applying a pressure using a press machine (hot press), a method of pressing it by heated rollers, a method of heating it in a furnace, and the like can be given.

According to the method (b), a cross-linkable resin shaped product of an arbitrary shape can be obtained. As the shape, a sheet shape, a film shape, a columnar shape, a cylindrical shape, a polygonal prism shape, and the like can be given.

As the mold used herein, a conventionally known shaping mold, for example, a shaping mold having a split mold structure, i.e. having a core mold and a cavity mold, may be used. The polymerizable composition is injected into the cavity of them and bulk-polymerized. The core mold and the cavity mold are produced so as to form a cavity matching the shape of a product to be molded. The shape, material, size, and the like of the shaping mold are not particularly limited. Further, by preparing plate-shaped molds such as glass-plate molds or metal-plate molds and a spacer of a predetermined thickness and injecting and bulk-polymerizing the polymerizable composition in a space formed by the two plate-shaped molds sandwiching the spacer, it is possible to obtain a sheet-shaped or film-shaped cross-linkable shaped product.

The filling pressure (injection pressure) when filling the polymerizable composition into the cavity of the shaping mold is usually 0.01 to 10 MPa and preferably 0.02 to 5 MPa. If the filling pressure is too low, the transfer of transfer surfaces formed on the inner circumference of the cavity tends not to be carried out satisfactorily, while if the filling pressure is too high, the shaping mold should be increased in rigidity, which is not economical. The mold clamping pressure is usually in a range of 0.01 to 10 MPa. As a method of heating the polymerizable composition, a method of using a heating means such as an electric heater, steam, or the like provided for the shaping mold, a method of heating the shaping mold in an electric furnace, and the like can be given.

The method (c) is suitably used for obtaining a sheet-shaped or film-shaped cross-linkable resin shaped product. The thickness of the obtained shaped product is usually in a range of 0.001 to 10 mm, preferably 0.005 to 1 mm, and more preferably 0.01 to 0.5 mm. If it is in this range, the shapeability at the time of lamination and the mechanical strength, toughness, and the like of the laminate are improved, which is thus preferable. For example, the polymerizable composition can be impregnated in the fiber reinforcing material by coating a predetermined amount of the polymerizable composition on the fiber reinforcing material by a known method such as a spray coating method, a dip coating method, a roll coating method, a curtain coating method, a die coating method, or a split coating method, placing a protective film thereon if desired, and pressing from above with a roller or the like. After the polymerizable composition is impregnated in the fiber reinforcing material, the impregnated material is heated to a predetermined temperature to bulk-polymerize the polymerizable composition, thereby obtaining a desired cross-linkable resin shaped product. In the cross-likable resin shaped product, the content of the fiber reinforcing material is usually in a range of 10 to 90 wt %, preferably 20 to 80 wt %, and more preferably 30 to 70 wt %. If it is in this range, the dielectric characteristics and mechanical strength of the laminate to be obtained are balanced, which is thus preferable.

As the fiber reinforcing material, inorganic-based and/or organic-based fiber can be used. For example, organic fibers such as a PET (polyethylene terephthalate) fiber, aramide fiber, super-high molecular weight polyethylene fiber, polyamide (nylon) fiber, and liquid crystal polyester fiber; inorganic fibers such as a glass fiber, carbon fiber, alumina fiber, tungsten fiber, molybdenum fiber, Budene fiber, titanium fiber, steel fiber, boron fiber, silicon carbide fiber, and silica fiber; and the like can be given. Of these, the organic fibers and the glass fiber are preferable. In particular, the aramide fiber, the liquid crystal polyester fiber, and the glass fiber are preferable. As the glass fiber, a fiber of E glass, NE glass, S glass, D glass, H glass, or the like can be suitably used.

These may be used alone or in combination of two or more kinds. The form of the fiber reinforcing material is not particularly limited. For example, a mat, a cloth, a nonwoven fabric, and the like can be given.

As a method of heating the impregnated material comprising the fiber reinforcing material and the polymerizable composition impregnated therein, for example, a method of placing the impregnated material on a support member and then heating it as in the above-mentioned method (a), a method of placing the fiber reinforcing material in a mold in advance and impregnating the polymerizable composition in the mold to obtain an impregnated material, and then heating it as in the above-mentioned method (b), and the like can be given.

In each of the methods (a), (b), and (c), the heating temperature for polymerizing the polymerizable composition is usually in a range of 30 to 250° C., preferably 50 to 200° C., and more preferably 90 to 150° C. and is usually the one-minute half-life temperature of the radical generator as the cross-linking agent or less, preferably 10° C. below the one-minute half-life temperature or less, and more preferably 20° C. below the one-minute half-life temperature or less. Further, the polymerization time may be suitably selected, but is usually 1 second to 20 minutes, and preferably 10 seconds to 5 minutes. By heating the polymerizable composition under these conditions, a cross-linkable resin shaped product with little unreacted monomer is obtained, which is thus preferable.

The polymer which forms the cross-linkable resin shaped product thus obtained does not substantially have a cross-linked structure and, for example, can be dissolved in toluene. The molecular weight of the polymer is usually in a range of 1,000 to 1,000,000, preferably 5,000 to 500,000, and more preferably 10,000 to 100,000 in terms of a polystyrene converted weight average molecular weight measured by gel permeation chromatography (eluant: tetrahydrofuran).

The cross-linkable resin shaped product according to this invention is a post cross-linkable resin shaped product while part of its constituent resin may be cross-linked. For example, when the polymerizable composition is bulk-polymerized in the mold, the heat of the polymerization reaction is difficult to dissipate at the center portion of the mold so that part of the inside of the mold may become too high in temperature. At the high temperature portion, a cross-linking reaction may occur to cause cross-linking. However, if the surface portion where the heat easily dissipates is formed of a post cross-linkable resin, the cross-linkable resin shaped product of this invention can sufficiently achieve the desired effect.

The cross-linkable resin shaped product according to this invention is obtained by the completion of bulk polymerization. Therefore, there is no possibility of a polymerization reaction further proceeding during storage. The cross-linkable resin shaped product of this invention contains the cross-linking agent such as the radical generator. However, unless the cross-linkable resin shaped product is heated to a temperature, which causes a cross-linking reaction, or higher, no inconvenience such as a change in surface hardness occurs and thus the cross-linkable resin shaped product is excellent in storage stability.

The cross-linkable resin shaped product according to this invention is suitably used, for example, as a prepreg in the manufacture of a cross-linked resin shaped product and a laminate of this invention.

(Cross-Linked Resin Shaped Product)

A cross-linked resin shaped product which will be described herein is formed by bulk-polymerizing the polymerizable composition of this invention and cross-linking an obtained polymer. Such a cross-linked resin shaped product is, for example, obtained by cross-linking the above-mentioned cross-linkable resin shaped product. The cross-linkable resin shaped product can be cross-linked by maintaining the shaped product at a temperature, where a cross-linking reaction occurs in the polymer forming the shaped product, or higher. The heating temperature is usually a temperature, at which a cross-linking reaction is induced by the cross-linking agent, or higher. For example, when the radical generator is used as the cross-linking agent, the heating temperature is the one-minute half-life temperature or higher, preferably 5° C. above the one-minute half-life temperature or higher, and more preferably 10° C. above the one-minute half-life temperature or higher. Typically, it is in a range of 100 to 300° C. and preferably 150 to 250° C. The heating time is in a range of 0.1 to 180 minutes, preferably 0.5 to 120 minutes, and more preferably 1 to 60 minutes.

Further, by maintaining the polymerizable composition of this invention at the temperature, where the above-mentioned cross-linkable resin shaped product cross-links, or higher, specifically, by heating it at the temperature and for the time described herein, it is possible to cause bulk polymerization of the cycloolefin monomer and a cross-linking reaction in the cycloolefin polymer produced by such polymerization to proceed together, thereby manufacturing a cross-linked resin shaped product of this invention. When manufacturing the cross-linked resin shaped product in this manner, if, for example, a copper foil is used as a support member according to the method (a), it is possible to obtain a copper clad laminate (CCL).

Hereinbelow, aspects achievable by this invention will be described.

(Aspect 1)

A semiconductor device characterized by using the multilayer wiring board according to each embodiment described above as a board for mounting a semiconductor element.

(Aspect 2)

The semiconductor device according to the aspect 1, characterized in that the semiconductor element and the multilayer wiring board are accommodated in the same package.

(Aspect 3)

The semiconductor device according to the aspect 1 or 2, characterized in that a signal having a frequency of 8 GHz or less propagates in the first wiring region and a signal having a frequency exceeding 8 GHz propagates in the second wiring region.

(Aspect 4)

The semiconductor device according to any one of the aspects 1 to 3, characterized in that the second wiring region includes a portion where a signal exceeding 8 GHz propagates for 1 cm or more.

(Aspect 5)

An electronic device characterized by using the multilayer wiring board according to any one of the aspects 1 to 6 as a board for mounting a plurality of electronic components.

(Aspect 6)

The electronic device according to the aspect 5, characterized in that the plurality of electronic components and the multilayer wiring board are accommodated in the same case.

(Aspect 7)

The electronic device according to the aspect 5 or 6, characterized in that a signal having a frequency of 8 GHz or less propagates in the first wiring region and a signal having a frequency exceeding 8 GHz propagates in the second wiring region.

(Aspect 8)

The semiconductor device according to any one of aspects 5 to 7, characterized in that the second wiring region includes a portion where a signal exceeding 8 GHz propagates for 1 cm or more.

### DESCRIPTION OF SYMBOLS

100 multilayer wiring board
101 first wiring region (high-density mounting region)
102 second wiring region (high-frequency propagation region)
103a, 103b, 103c, 103d first to fourth wiring layers
104, 104a, 104b, 104c, 104d insulating layers
105 conductive film (ground electrode)

1. A multilayer wiring board, in which a plurality of wiring layers are laminated through an insulating layer, comprising a first wiring region where wiring and insulating layers are alternately laminated and a second wiring region where, compared to the first wiring region, a thickness of an insulating layer is twice or more and a width of a wiring layer is twice or more, wherein the first wiring region and the second wiring region are integrally formed in the same board, wherein the insulating layer is made of a resin material formed by bulk-polymerizing and cross-linking a polymerizable composition which contains a cycloolefin monomer, a polymerization catalyst, a cross-linking agent, a bifunctional compound having two vinylidene groups, and a trifunctional compound having three vinylidene groups and in which a content ratio of the bifunctional compound and the trifunctional compound is 0.5 to 1.5 in terms of a weight ratio value (bifunctional compound/trifunctional compound).

2. The multilayer wiring board according to claim 1, wherein the second wiring region includes a portion comprising a third insulating layer with a thickness greater than the thickness of the insulating layer of the second wiring region and a third wiring layer provided on the third insulating layer and having a width greater than the width of the wiring layer of the second wiring region.

3. The multilayer wiring board according to claim 1, wherein the width of the wiring layer in the second wiring region is 30 μm or more and the thickness of the insulating layer in the second wiring region is 40 μm or more.

4. The multilayer wiring board according to claim 1, wherein a conductor is formed to penetrate an insulating layer at a boundary portion between the first wiring region and the second wiring region and is grounded.

5. The multilayer wiring board according to claim 1, wherein a characteristic impedance of a wiring pattern formed by the wiring layer in the second wiring region is 100Ω or more.

6. The multilayer wiring board according to claim 1, wherein the insulating layer at least in the second wiring region of the first and second wiring regions is made of the resin material with a relative permittivity of 3.7 or less and a dissipation factor of 0.0015 or less.

7. A semiconductor device characterized by using the multilayer wiring board according to claim 1 as a board for mounting a semiconductor element.

8. The semiconductor device according to claim 7, wherein the semiconductor element and the multilayer wiring board are accommodated in the same package.

9. The semiconductor device according to claim 7, wherein a signal having a frequency of 8 GHz or less propagates in the first wiring region and a signal having a frequency exceeding 8 GHz propagates in the second wiring region.

10. The semiconductor device according to claim 7, wherein the second wiring region includes a portion where a signal exceeding 8 GHz propagates for 1 cm or more.

11. An electronic device characterized by using the multilayer wiring board according to claim 1 as a board for mounting a plurality of electronic components.

12. The electronic device according to claim 11, wherein the plurality of electronic components and the multilayer wiring board are accommodated in the same case.

13. The electronic device according to claim 11, wherein a signal having a frequency of 8 GHz or less propagates in the first wiring region and a signal having a frequency exceeding 8 GHz propagates in the second wiring region.

14. The electronic device according to claim 11, wherein the second wiring region includes a portion where a signal exceeding 8 GHz propagates for 1 cm or more.
